(19) United States
(12) Patent Application Publication
(10) Pub. No.: US 2026/0173515 A1
(43) Pub. Date: Jun. 18, 2026

(54) SEMICONDUCTOR DEVICE AND METHOD OF FABRICATING THE SAME

(71) Applicant: Samsung Electronics Co., Ltd., Suwon-si (KR)

(72) Inventors: Minseok SHIN, Suwon-si (KR); Heeyoung PARK, Suwon-si (KR); Jeongyeon SEO, Suwon-si (KR); Kwang-Yong YANG, Suwon-si (KR); Wonhyuk LEE, Suwon-si (KR); Ji-Eun HAN, Suwon-si (KR)

(21) Appl. No.: 19/207,777

(22) Filed: May 14, 2025

(30) Foreign Application Priority Data
Dec. 17, 2024 (KR) 10-2024-0188686

(51) Int. Cl. H10D 84/85; H01L 23/522; H01L 23/528; H10D 30/00; H10D 30/01; H10D 62/13; H10D 64/23; H10D 84/01

(52) U.S. Cl. CPC H10D 84/851; H10D 30/503; H10D 30/506; H10D 62/151; H10D 64/257; H10W 20/42; H10W 20/43; H10W 20/435; H10W 20/495; H10D 30/0191; H10D 84/0186; H10D 84/0188

(57) ABSTRACT

A semiconductor device may include a first active contact, a second active contact, and a cutting pattern disposed between the first and second active contacts. Each of the first and second active contacts may include a conductive pattern having a first side surface and a second side surface. A barrier pattern may be provided to cover the first side surface of the conductive pattern and extended to a bottom surface of the conductive pattern. The cutting pattern may be in contact with the second side surface of the conductive pattern of each of the first and second active contacts.

### CROSS-REFERENCE TO PRIORITY APPLICATION

This U.S. non-provisional patent application claims priority under 35 U.S.C. § 119 to Korean Patent Application No. 10-2024-0188686, filed on Dec. 17, 2024, in the Korean Intellectual Property Office, the entire contents of which are hereby incorporated by reference.

### BACKGROUND OF THE INVENTION

The present disclosure relates to a semiconductor device and a method of fabricating the same, and in particular, to a semiconductor device including a field effect transistor and a method of fabricating the same.

Semiconductor devices may include integrated circuits such as metal-oxide-semiconductor field-effect transistors (MOSFETs). To meet increasing demand for semiconductor devices with small pattern sizes and reduced design rules, MOSFETs may be aggressively scaled down. The scale-down of MOSFETs may lead to deterioration in operational properties of the semiconductor devices. A variety of research is being conducted in light of technical limitations associated with the scale-down of semiconductor devices and to realize high-performance semiconductor devices.

### SUMMARY

An embodiment of the inventive concept provides a semiconductor device with improved electrical characteristics.

An embodiment of the inventive concept provides a method of fabricating a semiconductor device with improved reliability.

According to an embodiment of the inventive concept, a semiconductor device may include a substrate including a first active pattern and a second active pattern, which are spaced apart from each other in a first direction, a first source/drain pattern on the first active pattern, a second source/drain pattern on the second active pattern, a first active contact disposed on the first source/drain pattern, a second active contact disposed on the second source/drain pattern, and a cutting pattern disposed between the first and second active contacts. Each of the first and second active contacts may include a conductive pattern having a first side surface and a second side surface, which are opposite to each other in the first direction, and a barrier pattern provided to cover the first side surface of the conductive pattern and extended to a bottom surface of the conductive pattern. The cutting pattern may be in contact with the second side surface of the conductive pattern of each of the first and second active contacts, and the first direction may be parallel to a top surface of the substrate.

According to an embodiment of the inventive concept, a semiconductor device may include a substrate including a first active pattern and a second active pattern, which are spaced apart from each other in a first direction parallel to a top surface of the substrate, a first source/drain pattern on the first active pattern, a second source/drain pattern on the second active pattern, a first active contact disposed on the first source/drain pattern, a second active contact disposed on the second source/drain pattern, and a cutting pattern disposed between the first and second active contacts.

The first active contact may include a first conductive pattern, and the first conductive pattern may include a first body portion disposed on the first source/drain pattern, and a first via portion extended from the first body portion in a third direction. The second active contact may include a second conductive pattern, and the second conductive pattern may include a second body portion disposed on the second source/drain pattern, and a second via portion extended from the second body portion in the third direction. A top surface of the cutting pattern may be located at a level higher than a top surface of the first body portion and a top surface of the second body portion, and the third direction may be perpendicular to the top surface of the substrate.

According to an embodiment of the inventive concept, a semiconductor device may include a substrate including a first active pattern and a second active pattern, which are spaced apart from each other in a first direction parallel to a top surface of the substrate, a device isolation layer filling a space between the first and second active patterns, a first source/drain pattern on the first active pattern, a second source/drain pattern on the second active pattern, a first interlayer insulating layer disposed on the device isolation layer to cover the first and second source/drain patterns, a first active contact disposed on the first source/drain pattern to penetrate a portion of the first interlayer insulating layer, a second active contact disposed on the second source/drain pattern to penetrate a portion of the first interlayer insulating layer, and a cutting pattern disposed between the first and second active contacts. The first active contact may include a first body portion disposed on the first source/drain pattern and a first via portion extended from the first body portion in a third direction. The second active contact may include a second body portion disposed on the second source/drain pattern and a second via portion extended from the second body portion in the third direction.

A top surface of the cutting pattern may be located at a level higher than a top surface of each of the first and second body portions.

### BRIEF DESCRIPTION OF THE DRAWINGS

FIGS. 1 to 3 are conceptual diagrams illustrating logic cells of a semiconductor device according to an embodiment of the inventive concept.

FIG. 4 is a plan view illustrating a semiconductor device according to an embodiment of the inventive concept.

FIGS. 5A to 5D are sectional views illustrating a semiconductor device according to an embodiment of the inventive concept.

FIGS. 6A-6D are sectional views illustrating a method of fabricating a semiconductor device according to an embodiment of the inventive concept.

FIGS. 7A-7D are sectional views illustrating a method of fabricating a semiconductor device according to an embodiment of the inventive concept.

FIGS. 8A-8D are sectional views illustrating a method of fabricating a semiconductor device according to an embodiment of the inventive concept.

FIGS. 9A-9D are sectional views illustrating a method of fabricating a semiconductor device according to an embodiment of the inventive concept.

FIGS. 10A-10D are sectional views illustrating a method of fabricating a semiconductor device according to an embodiment of the inventive concept.

FIGS. 11A-11D are sectional views illustrating a method of fabricating a semiconductor device according to an embodiment of the inventive concept.

FIGS. 12A-12D are sectional views illustrating a method of fabricating a semiconductor device according to an embodiment of the inventive concept.

FIGS. 13A-13D are sectional views illustrating a method of fabricating a semiconductor device according to an embodiment of the inventive concept.

FIGS. 14A-14D are sectional views illustrating a method of fabricating a semiconductor device according to an embodiment of the inventive concept.

FIGS. 15A-15D are sectional views illustrating a method of fabricating a semiconductor device according to an embodiment of the inventive concept.

FIGS. 16A-16D are sectional views illustrating a method of fabricating a semiconductor device according to an embodiment of the inventive concept.

FIGS. 17A-17D are sectional views illustrating a method of fabricating a semiconductor device according to an embodiment of the inventive concept.

### DETAILED DESCRIPTION

Example embodiments of the inventive concepts will now be described more fully with reference to the accompanying drawings, in which example embodiments are shown.

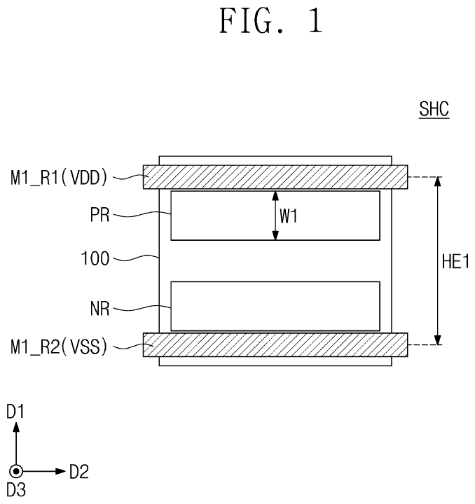

FIGS. 1 to 3 are conceptual diagrams illustrating logic cells of a semiconductor device according to an embodiment of the inventive concept.

Referring to FIG. 1, a single height cell SHC may be provided. In detail, a first power line M1_R1 and a second power line M1_R2 may be provided on a substrate 100. The first power line M1_R1 may be a conduction path, to which a drain voltage VDD (e.g., a power voltage) is provided. The second power line M1_R2 may be a conduction path, to which a source voltage VSS (e.g., a ground voltage) is provided.

The single height cell SHC may be defined between the first power line M1_R1 and the second power line M1_R2. The single height cell SHC may include one PMOSFET region PR and on NMOSFET region NR. In other words, the single height cell SHC may have a CMOS structure provided between the first power line M1_R1and the second power line M1_R2.

Each of the PMOSFET and NMOSFET regions PR and NR may have a first width W1 in a first direction D1. A length of the single height cell SHC in the first direction D1 may be defined as a first height HE1. The first height HE1 may be substantially equal to a distance (e.g., a pitch) between the first and second power lines M1_R1 and M1_R2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

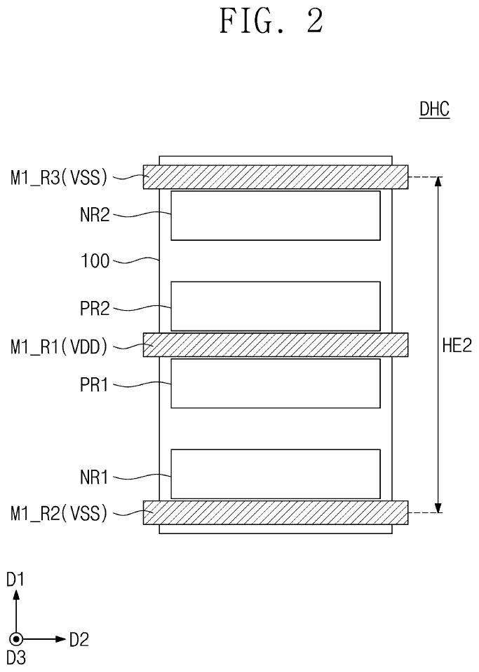

Referring to FIG. 2, a double height cell DHC may be provided. In detail, a first power line M1_R1, a second power line M1_R2, and a third power line M1_R3 may be provided on the substrate 100. The first power line M1_R1 may be disposed between the second power line M1_R2 and the third power line M1_R3. The third power line M1_R3 may be a conduction path, to which the drain voltage VDD is provided.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to the first power line M1_R1. When viewed in a plan view, the first power line M1_R1 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region.

Thus, a channel size of a PMOS transistor of the double height cell DHC may be larger than a channel size of a PMOS transistor of the single height cell SHC previously described with reference to FIG. 1. For example, the channel size of the PMOS transistor of the double height cell DHC may be about two times the channel size of the PMOS transistor of the single height cell SHC. In this case, the double height cell DHC may be operated at a higher speed than the single height cell SHC. In an embodiment, the double height cell DHC shown in FIG. 2 may be defined as a multi-height cell. Although not shown, the multi-height cell may include a triple height cell whose cell height is about three times that of the single height cell SHC.

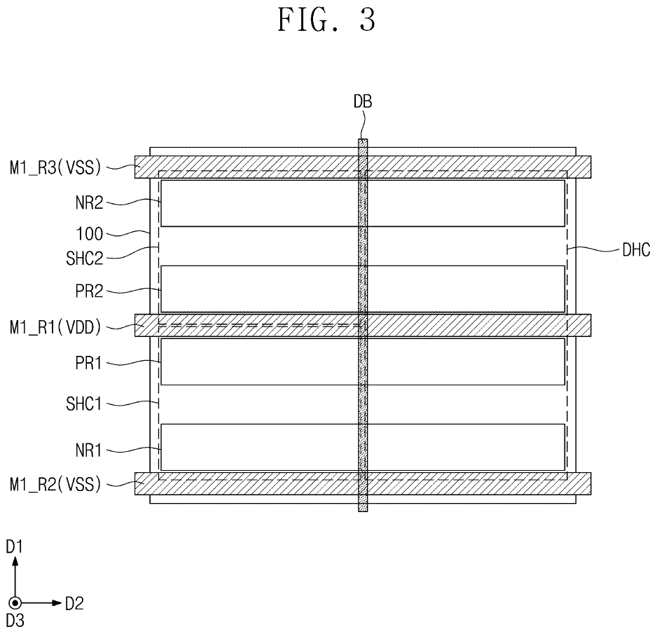

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

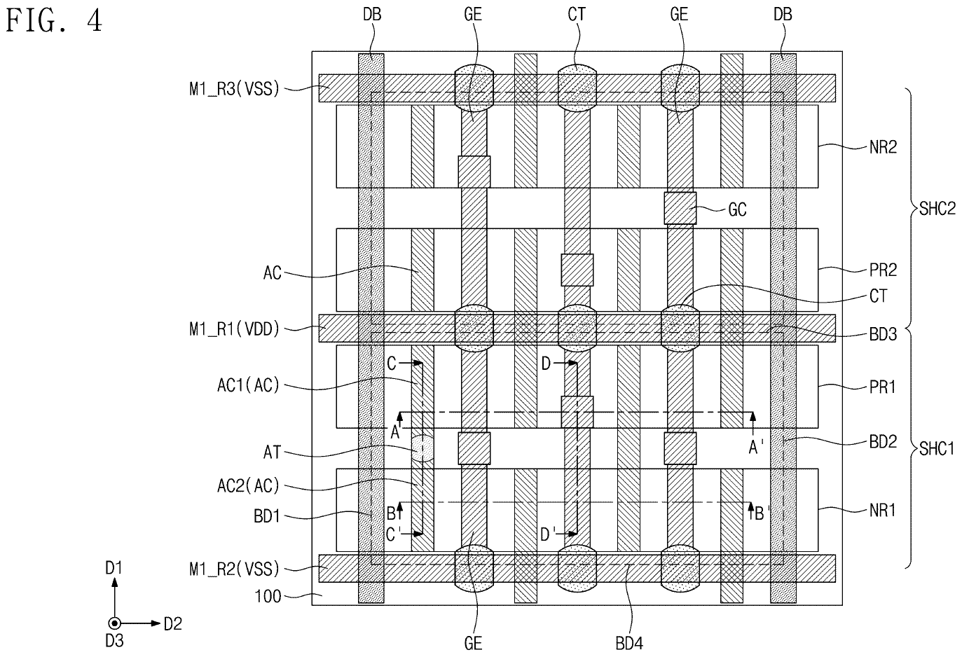

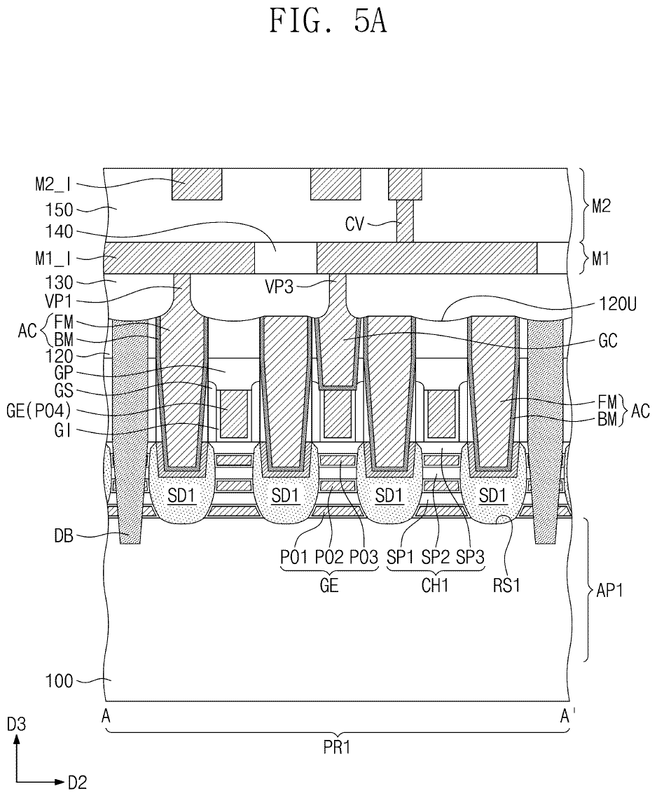

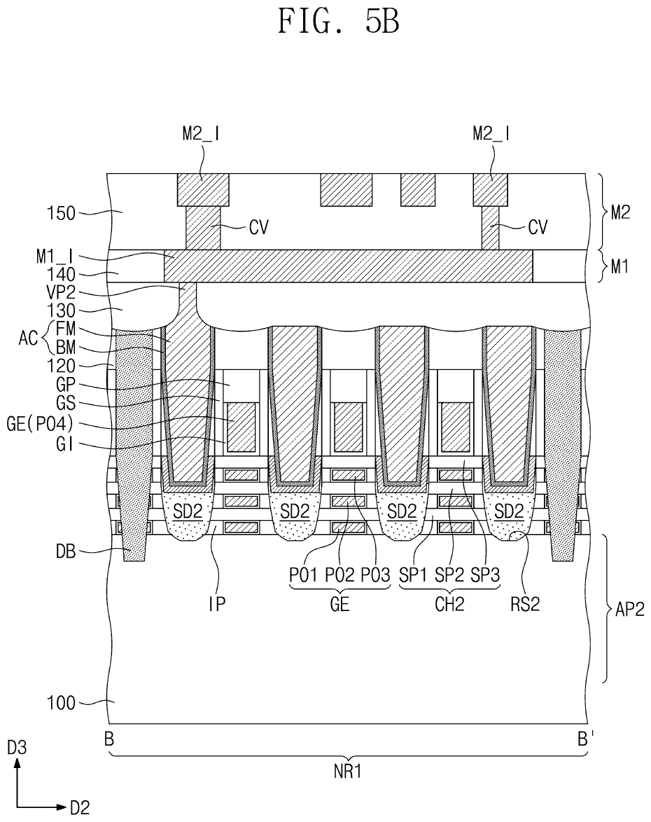

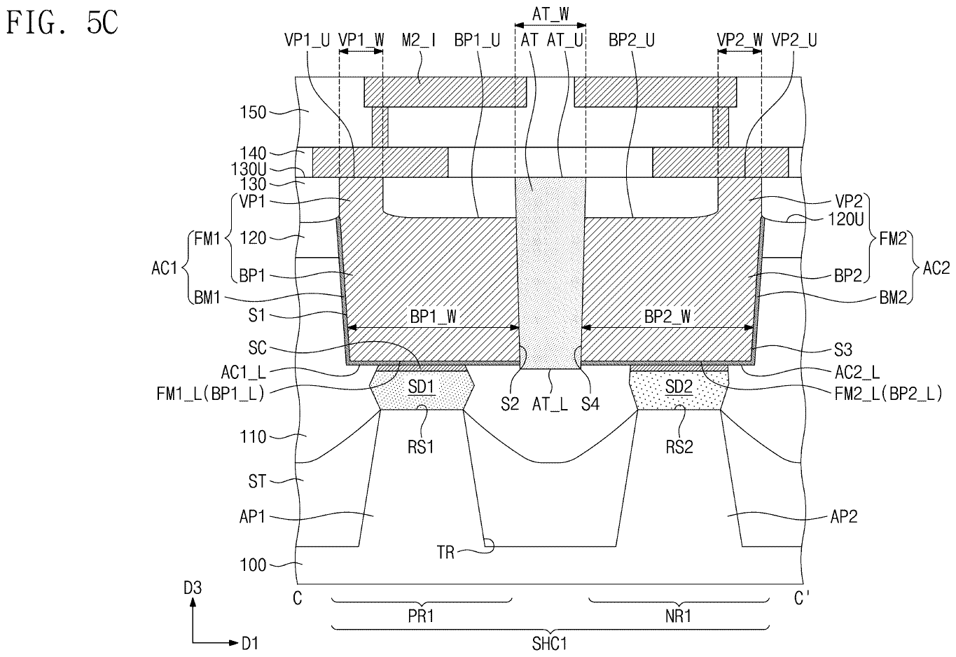

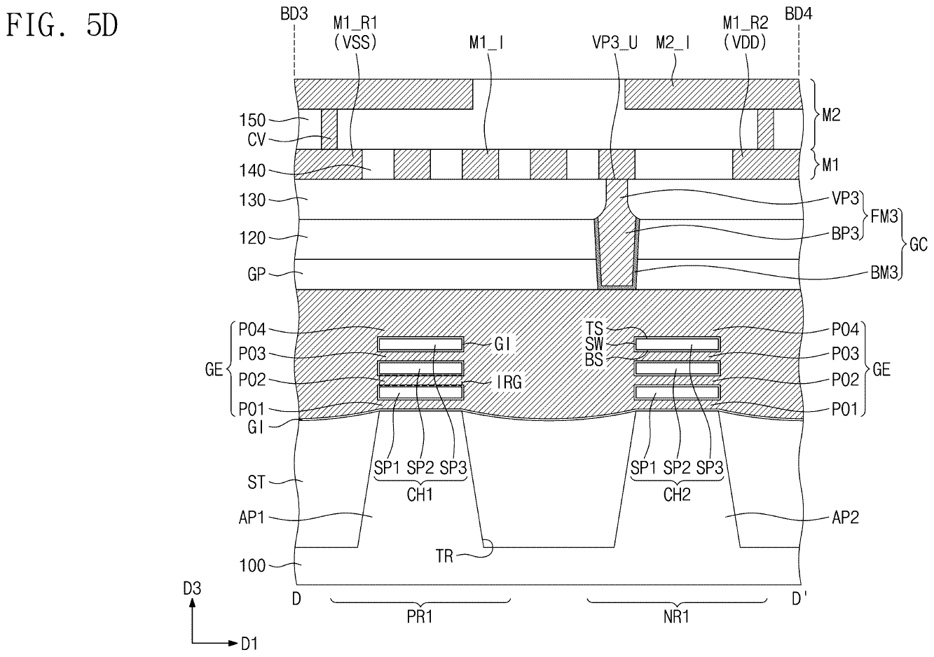

FIG. 4 is a plan view illustrating a semiconductor device according to an embodiment of the inventive concept. FIGS. 5A to 5D are sectional views illustrating a semiconductor device according to an embodiment of the inventive concept. FIG. 5A is a sectional view taken along a line A-A′ of FIG. 4. FIG. 5B is a sectional view taken along a line B-B′ of FIG. 4. FIG. 5C is a sectional view taken along a line C-C′ of FIG. 4. FIG. 5D is a sectional view taken along a line D-D′ of FIG. 4. For concise description, an element previously described with reference to FIGS. 1 to 3 may be identified by the same reference number without repeating an overlapping description thereof.

Referring to FIGS. 4 and 5A to 5D, the first and second single height cells SHC1 and SHC2 may be provided on the substrate 100. Logic transistors constituting a logic circuit may be disposed on each of the first and second single height cells SHC1 and SHC2. The substrate 100 may be a semiconductor substrate, which is made of silicon, germanium, silicon-germanium, or a compound semiconductor material.

The substrate 100 may have a first PMOSFET region PR1, a second PMOSFET region PR2, a first NMOSFET region NR1, and a second NMOSFET region NR2. The first PMOSFET region PR1, the second PMOSFET region PR2, the first NMOSFET region NR1, and the second NMOSFET region NR2 may be active regions. Each of the first PMOSFET region PR1, the second PMOSFET region PR2, the first NMOSFET region NR1, and the second NMOSFET region NR2 may be extended in a second direction D2, which is parallel to a top surface 100U of the substrate 100 and is not parallel to the first direction D1.

A first active pattern AP1 and a second active pattern AP2 may be defined by a trench TR, which is formed in an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may be extended in the second direction D2. The first and second active patterns AP1 and AP2 may be vertically protruding portions of the substrate 100, which are extended in a third direction D3 perpendicular to the top surface of the substrate.

A device isolation layer ST may be provided to fill the trench TR. The device isolation layer ST may include a silicon oxide layer. The device isolation layer ST may be disposed between the first active pattern AP1 and the second active pattern.

A first source/drain pattern SD1 may be provided on each of the first and second PMOSFET regions PR1 and PR2. The first source/drain pattern SD1 may be provided on the first active pattern AP1. The first source/drain pattern SD1 may be an impurity region of a first conductivity type (e.g., p-type). A first channel pattern CH1 may be interposed between a pair of the first source/drain patterns SD1, which are adjacent to each other in the second direction D2, and may be disposed on the first active pattern AP1. The first channel pattern CH1 may include semiconductor patterns SP1, SP2, and SP3, which are provided on the first active pattern AP1 and are spaced apart from each other in the third direction D3. The pair of first source/drain patterns SD1 may be connected to the semiconductor patterns SP1, SP2, and SP3 of the first channel pattern CH1.

A second source/drain pattern SD2 may be provided on each of the first and second NMOSFET regions NR1 and NR2. The second source/drain pattern SD2 may be provided on the second active pattern AP2. The second source/drain pattern SD2 may have a second conductivity type (e.g., n-type) that is different from the first conductivity type. A second channel pattern CH2 may be interposed between a pair of the second source/drain patterns SD2, which are adjacent to each other in the second direction D2, and may be disposed on the second active pattern AP2. The second channel pattern CH2 may include the semiconductor patterns SP1, SP2, and SP3, which are provided on the second active pattern AP2 and are spaced apart from each other in the third direction D3. The pair of second source/drain patterns SD2 may be connected to the semiconductor patterns SP1, SP2, and SP3 of the second channel pattern CH2.

The first and second source/drain patterns SD1 and SD2 may be epitaxial patterns that are formed by a selective epitaxial growth process. As an example, the first and second source/drain patterns SD1 and SD2 may have top surfaces that are coplanar with top surfaces of the first and second channel patterns CH1 and CH2. As another example, the top surfaces of the first and second source/drain patterns SD1 and SD2 may be higher than the top surfaces of the first and second channel patterns CH1 and CH2.

The first source/drain pattern SD1 may be formed of or include a semiconductor material (e.g., SiGe) whose lattice constant is larger than a lattice constant of the first channel pattern CH1. In this case, the pair of first source/drain patterns SD1 may exert a compressive stress on the first channel pattern CH1 therebetween. In an embodiment, the second source/drain pattern SD2 may be formed of or include a semiconductor material (e.g., Si or SIC) whose lattice constant is smaller than or equal to a lattice constant of the second channel pattern CH2. In the case where the second source/drain pattern SD2 has a lattice constant smaller than that of the second channel pattern CH2, the pair of second source/drain patterns SD2 may exert a tensile stress on the second channel pattern CH2 therebetween.

A gate electrode GE may be extended in the first direction D1 to cross the first and second active patterns AP1 and AP2. The gate electrode GE may be vertically overlapped with the first and second channel patterns CH1 and CH2. Each of the gate electrodes GE may be provided to enclose a top surface and opposite side surfaces of each of the first and second channel patterns CH1 and CH2.

The first single height cell SHC1 may have a first border BD1 and a second border BD2, which are opposite to each other in the second direction D2. The first and second borders BD1 and BD2 may be extended in the first direction D1. The first single height cell SHC1 may have a third border BD3 and a fourth border BD4, which are opposite to each other in the first direction D1. The third and the fourth borders BD3 and BD4 may be extended in the second direction D2.

Gate cutting patterns CT may be disposed on the third and the fourth borders BD3 and BD4 of the first single height cell SHC1. The gate cutting patterns CT may be disposed on a border, in the second direction D2, of each of the first and second single height cells SHC1 and SHC2. When viewed in a plan view, the gate cutting patterns CT on the third and the fourth borders BD3 and BD4 may be disposed to be overlapped with the gate electrodes GE, respectively. The gate cutting patterns CT may be formed of or include an insulating material (e.g., silicon oxide or silicon nitride).

The gate electrode GE on the first single height cell SHC1 may be separated from the gate electrode GE on the second single height cell SHC2 by the gate cutting pattern CT. The gate cutting pattern CT may be interposed between the gate electrodes GE, which are respectively placed on the first and second single height cells SHC1 and SHC2 that are aligned to each other in the first direction D1. That is, the gate electrode GE extending in the first direction D1 may be divided into a plurality of gate electrodes GE by the gate cutting patterns CT.

The gate electrode GE may be extended in the first direction D1 to cross the first and second channel patterns CH1 and CH2. Each of the gate electrodes GE may be vertically overlapped with the first and second channel patterns CH1 and CH2. The gate electrode GE may include a first portion PO1 interposed between the active pattern (AP1 or AP2) and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

Referring to FIG. 5D, the gate electrode GE may be provided on a top surface TS, a bottom surface BS, and opposite side surfaces SW of each of the first to third semiconductor patterns SP1, SP2, and SP3. That is, the transistor according to the present embodiment may be a three-dimensional field effect transistor (e.g., MBCFET or GAAFET) in which the gate electrode GE is provided to three-dimensionally surround the channel pattern.

A pair of gate spacers GS may be disposed on opposite side surfaces, respectively, of the fourth portion PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. In an embodiment, the gate spacers GS may be formed of or include at least one of SiCN, SiCON, or SiN. In an embodiment, the gate spacers GS may have a multi-layered structure including at least two layers, each of which is made of SiCN, SiCON, or SiN.

A gate capping pattern GP may be provided on the gate electrode GE. The gate capping pattern GP may be extended along the gate electrode GE and in the first direction D1. The gate capping pattern GP may be formed of or include a material having an etch selectivity with respect to first and second interlayer insulating layers 110 and 120, which will be described below. In detail, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the opposite side surfaces SW of each of the first to the third semiconductor patterns SP1, SP2, and SP3. The gate insulating layer GI may cover a top surface of the device isolation layer ST below the gate electrode GE.

An insulating pattern IP may be provided on the first and second NMOSFET regions NR1 and NR2 and between the gate insulating layer GI and the second source/drain pattern SD2. The gate electrode GE may be spaced apart from the second source/drain pattern SD2 by the gate insulating layer GI and the insulating pattern IP. By contrast, on the first and second PMOSFET regions PR1 and PR2, the insulating pattern IP may be omitted.

The gate electrode GE may include a first metal pattern and a second metal pattern on the first metal pattern. The first metal pattern may be provided on the gate insulating layer GI and adjacent to the first to the third semiconductor patterns SP1, SP2, and SP3. By adjusting a thickness and composition of the first metal pattern, it may be possible to realize a transistor having a desired threshold voltage. For example, the first to third portions PO1, PO2, and PO3 of the gate electrode GE may be composed of the first metal pattern. The first and second metal patterns may have different work functions from each other.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of metal layers which are stacked.

The second metal pattern may include a metal whose resistance is lower than the first metal pattern. For example, the second metal pattern may include at least one metallic material, which is selected from the group consisting of tungsten (W), aluminum (Al), titanium (Ti), and tantalum (Ta). In an embodiment, the fourth portion PO4 of the gate electrode GE may include the first metal pattern and the second metal pattern on the first metal pattern.

A first interlayer insulating layer 110 may be provided on the substrate 100. The first interlayer insulating layer 110 may be provided to cover the gate spacers GS and the first and second source/drain patterns SD1 and SD2. A top surface of the first interlayer insulating layer 110 may be substantially coplanar with a top surface of the gate capping pattern GP and the top surfaces of the gate spacers GS.

A second interlayer insulating layer 120 may be disposed on the first interlayer insulating layer 110 to cover the gate capping pattern GP. A top surface 120U of the second interlayer insulating layer 120 may be recessed toward the substrate 100. A third interlayer insulating layer 130 may be provided on the second interlayer insulating layer 120. The third interlayer insulating layer 130 may be provided to fill the recessed the top surface 120U of the second interlayer insulating layer 120. A fourth interlayer insulating layer 140 may be provided on the third interlayer insulating layer 130. In an embodiment, the first to fourth interlayer insulating layers 110 to 140 may include a silicon oxide layer.

A pair of division structures DB, which are opposite to each other in the second direction D2, may be provided at both sides of each of the first and second single height cells SHC1 and SHC2. For example, the pair of division structures DB may be provided on the first and second borders BD1 and BD2 of the first single height cell SHC1, respectively. The division structure DB may be extended in the first direction D1 to be parallel to the gate electrode GE.

The division structure DB may be provided to penetrate the first and second interlayer insulating layers 110 and 120 and may be extended into the first and second active patterns AP1 and AP2. The division structure DB may be provided to penetrate an upper portion of each of the first and second active patterns AP1 and AP2. The division structure DB may electrically separate an active region of each of the first and second single height cells SHC1 and SHC2 from an active region of a neighboring cell.

Each of active contacts AC may be provided to penetrate the first and second interlayer insulating layers 110 and 120 and may be electrically connected to the first and second source/drain patterns SD1 and SD2, respectively. A first active contact AC1 may be electrically connected to the first source/drain pattern SD1 of the first PMOSFET region PR1. A second active contact AC2 may be electrically connected to the second source/drain pattern SD2 of the first NMOSFET region NR1.

Each of the active contacts AC may be provided between a pair of the gate electrodes GE. When viewed in a plan view, each of the active contacts AC may be a bar-or line-shaped pattern extending in the first direction D1.

The active contacts AC may be self-aligned contacts. For example, the active contacts AC may be formed in a self-aligned manner using the gate capping pattern GP and the gate spacers GS. In an embodiment, each of the active contacts AC may cover at least a portion of a side surface of each of the gate spacers GS. Although not shown, each of the active contacts AC may cover a portion of the top surface of the gate capping pattern GP.

The first active contact AC1 may include a first conductive pattern FM1 and a first barrier pattern BM1. The first conductive pattern FM1 may include a first side surface S1 and a second side surface S2, which are opposite to each other in the first direction D1. The first barrier pattern BM1 may cover the first side surface S1 of the first conductive pattern FM1 and a bottom surface FM1_L of the first conductive pattern FM1. The first barrier pattern BM1 may extend on the first side surface S1 of the first conductive pattern FM1. The first barrier pattern BM1 may extend between the bottom surface FM1_L of the first conductive pattern FM1 and the first source/drain pattern SD1.

The first conductive pattern FM1 may include a first body portion BP1 and a first via portion VP1, which is provided on the first body portion BP1 and is extended in the third direction D3. The first body portion BP1 may be disposed on the first source/drain pattern SD1 to penetrate the second and first interlayer insulating layers 120 and 110. A top surface BP1_U of the first body portion BP1 may be recessed toward the substrate 100. A width BP1_W of the first body portion BP1 in the first direction D1 may be larger than a width VP1_W of the first via portion VP1 in the first direction D1.

The first body portion BP1 may include the first and second side surfaces S1 and S2, which are opposite to each other in the first direction D1. The first and second side surfaces S1 and S2 of the first body portion BP1 may correspond to the first and second side surfaces S1 and S2, respectively, of the first conductive pattern FM1. That is, the first barrier pattern BM1 may cover the first side surface S1 and a bottom surface BP1_L of the first body portion BP1.

The first via portion VP1 may penetrate the third interlayer insulating layer 130 and may be connected to the first body portion BP1. The first via portion VP1 and the first body portion BP1 may form a single object or unit, i.e., a unitary element free of observable interfaces between portions thereof. In other words, there may be no interface between the first via portion VP1 and the first body portion BP1 such that the first via portion VP1 and the first body portion BP1 may be considered to be a unified, cohesive whole. A top surface VP1_U of the first via portion VP1 may be located at the same level as a top surface 130U of the third interlayer insulating layer 130.

The second active contact AC2 may include a second conductive pattern FM2 and a second barrier pattern BM2. The second conductive pattern FM2 may include a third side surface S3 and a fourth side surface S4, which are opposite to each other in the first direction D1. Here, the fourth side surface S4 of the second conductive pattern FM2 and the second side surface S2 of the first conductive pattern FM1 may face each other in the first direction D1. The second barrier pattern BM2 may cover the third side surface S3 of the second conductive pattern FM2 and a bottom surface FM2_L of the second conductive pattern FM2. The second barrier pattern BM2 may be interposed between the bottom surface FM2_L of the second conductive pattern FM2 and the second source/drain pattern SD2.

The second conductive pattern FM2 may include a second body portion BP2 and a second via portion VP2, which is provided on the second body portion BP2 and is extended in the third direction D3. The second body portion BP2 may be disposed on the second source/drain pattern SD2 to penetrate the second and first interlayer insulating layers 120 and 110. A top surface BP2_U of the second body portion BP2 may be recessed toward the substrate 100. A width BP2_W of the second body portion BP2 in the first direction D1 may be larger than a width VP2_W of the second via portion VP2 in the first direction D1.

The second body portion BP2 may include the third and fourth side surfaces S3 and S4, which are opposite to each other in the first direction D1. The third and fourth side surfaces S3 and S4 of the second body portion BP2 may correspond to the third and fourth side surfaces S3 and S4, respectively, of the second conductive pattern FM2. That is, the second barrier pattern BM2 may cover the third side surface S3 and a bottom surface BP2_L of the second body portion BP2.

The second via portion VP2 may be provided to penetrate the third interlayer insulating layer 130 and may be connected to the second body portion BP2. The second via portion VP2 and the second body portion BP2 may form a single object or unit, i.e., a unitary element free of observable interfaces between portions thereof. In other words, there may be no interface between the second via portion VP2 and the second body portion BP2 such that the second via portion VPs and the second body portion BP2 may be considered to be a unified, cohesive whole. A top surface VP2_U of the second via portion VP2 may be located at the same level as the top surface 130U of the third interlayer insulating layer 130.

Each of the first and second conductive patterns FM1 and FM2 may include a low resistance metal. Each of the first and second barrier patterns BM1 and BM2 may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

In an embodiment, the first via portion VP1 and the first body portion BP1 may form a single object, and the second via portion VP2 and the second body portion BP2 may form a single object. In other words, there may be no interface between the first body portion BP1 and the first via portion VP1 and between the second body portion BP2 and the second via portion VP2, and thus, the electric resistance of the active contact AC may be reduced. As a result, the semiconductor device with improved electrical characteristics may be provided.

Silicide patterns SC may be respectively interposed between the active contacts AC and the first and second source/drain patterns SD1 and SD2. The active contacts AC may be electrically connected to the first and second source/drain patterns SD1 and SD2, respectively through the silicide patterns SC. The silicide patterns SC may be formed of or include at least one of metal silicide materials (e.g., titanium silicide, tantalum silicide, tungsten silicide, nickel silicide, and cobalt silicide).

A cutting pattern AT may be disposed between the first active contact AC1 and the second active contact AC2. The cutting pattern AT may be provided to penetrate the first to third interlayer insulating layers 110, 120, and 130. The cutting pattern AT may be in contact with the second side surface S2 of the first conductive pattern FM1 and the fourth side surface S4 of the second conductive pattern FM2, free of the barrier patterns BM1 or BM2 therebetween. A top surface AT_U of the cutting pattern AT may be located at the same level as the top surface 130U of the third interlayer insulating layer 130, the top surface VP1_U of the first via portion VP1, and the top surface VP2_U of the second via portion VP2. The top surface AT_U of the cutting pattern AT may be located at a level higher than the top surface BP1_U of the first body portion BP1 and the top surface BP2_U of the second body portion BP2. The top surface AT_U of the cutting pattern AT may be located at a level higher than the top surface 120U of the second interlayer insulating layer 120. A bottom surface AT_L of the cutting pattern AT may be located at a level, which is equal to or lower than a bottom surface AC1_L of the first active contact AC1 and a bottom surface AC2_L of the second active contact AC2. In an embodiment, a width AT_W of the cutting pattern AT in the first direction D1 may range from 15 nm to 20 nm.

The cutting pattern AT may include a low-k dielectric material. For example, a dielectric constant of the cutting pattern AT may be lower than dielectric constants of the first interlayer insulating layer 110, the second interlayer insulating layer 120, and/or the third interlayer insulating layer 130. In an embodiment, the cutting pattern AT may be formed of or include SiOC.

According to an embodiment of the inventive concept, the cutting pattern AT may include a low-k dielectric material, and in this case, it may be possible to reduce a parasitic capacitance between adjacent ones of the active contacts AC. As a result, the semiconductor device with improved electrical characteristics may be provided.

In an embodiment, the width AT_W of the cutting pattern AT in the first direction D1 may be small. For example, the width AT_W of the cutting pattern AT in the first direction D1 may range from 15 nm to 20 nm. Since the width AT_W of the cutting pattern AT in the first direction D1 is small, the area loss of the active contact AC may be small. Thus, the semiconductor device with improved electrical characteristics may be provided.

A gate contact GC may be disposed on the gate electrode GE. The gate contact GC may include a third conductive pattern FM3 and a third barrier pattern BM3. The third conductive pattern FM3 may include a third body portion BP3 and a third via portion VP3, which is provided on and extended from the third body portion BP3 in the third direction D3. The third body portion BP3 may be disposed on the gate electrode GE to penetrate the second interlayer insulating layer 120 and the gate capping pattern GP. The third barrier pattern BM3 may cover side and bottom surfaces of the third body portion BP3.

The third via portion VP3 may be provided to penetrate the third interlayer insulating layer 130 and may be connected to the third body portion BP3. The third body portion BP3 and the third via portion VP3 may form a single object or unit, i.e., there may be no interface between the third body portion BP3 and the third via portion VP3 such that the third via portion VP3 and the third body portion BP3 may be considered to be a unified, cohesive whole. A top surface of the third via portion VP3 may be coplanar with the top surface 130U of the third interlayer insulating layer 130, the top surface VP1_U of the first via portion VP1, and the top surface VP2_U of the second via portion VP2. A top surface VP3_U of the third via portion VP3 may be located at a level higher than the top surface BP1_U of the first body portion BP1 and the top surface BP2_U of the second body portion BP2.

The third conductive pattern FM3 may include a low resistance metal. The third barrier pattern BM3 may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

The fourth interlayer insulating layer 140 may be disposed on the third interlayer insulating layer 130. A first metal layer M1 may be provided in the fourth interlayer insulating layer 140. For example, the first metal layer M1 may include the first power line M1_R1, the second power line M1_R2, and first interconnection lines M1_I. The interconnection lines M1_R1, M1_R2, and M1_I of the first metal layer M1 may be extended in the second direction D2 and parallel to each other.

In detail, the first and second power lines M1_R1 and M1_R2 may be respectively provided on the third and fourth borders BD3 and BD4 of the single height cell SHC. The first power line M1_R1 may be extended along the third border BD3 and in the second direction D2. The second power line M1_R2 may be extended along the fourth border BD4 and in the second direction D2.

The first interconnection lines M1_I of the first metal layer M1 may be disposed between the first and second power lines M1_R1 and M1_R2. The first interconnection lines M1_I of the first metal layer M1 may be arranged at a second pitch in the first direction D1. The second pitch may be smaller than the first pitch. A line width of each of the first interconnection lines M1_I may be smaller than a line width of each of the first and second power lines M1_R1 and M1_R2.

The interconnection lines M1_R1, M1_R2, and M1_I in the first metal layer M1 may be electrically connected to the first, second, and third via portions VP1, VP2, and VP3, respectively. In detail, the first via portion VP1 of the first active contact AC1 may be electrically connected to the interconnection line of the first metal layer M1. The second via portion VP2 of the second active contact AC2 may be electrically connected to the interconnection line of the first metal layer M1, and the third via portion VP3 of the gate contact may be electrically connected to the interconnection line of the first metal layer M1.

A second metal layer M2 may be provided in a fifth interlayer insulating layer 150. The second metal layer M2 may include a plurality of second interconnection lines M2_I. Each of the second interconnection lines M2_I of the second metal layer M2 may be a line-or bar-shaped pattern extending in the first direction D1. That is, the second interconnection lines M2_I may be extended in the first direction D1 and parallel to each other.

The second metal layer M2 may further include connection vias CV, which are placed below the second interconnection lines M2_I, respectively. The interconnection lines of the first and second metal layers M1 and M2 may be electrically connected to each other through the connection via VI2.

The interconnection lines of the first and second metal layers M1 and M2 may be formed of or include the same conductive material or different conductive materials. For example, the interconnection lines of the first and second metal layers M1 and M2 may be formed of or include at least one of metallic materials (e.g., aluminum, copper, tungsten, ruthenium, molybdenum, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

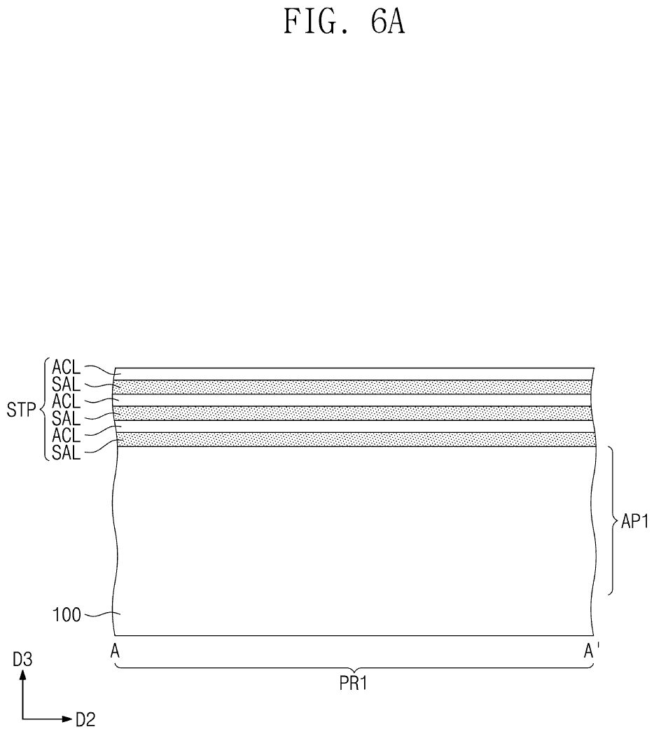

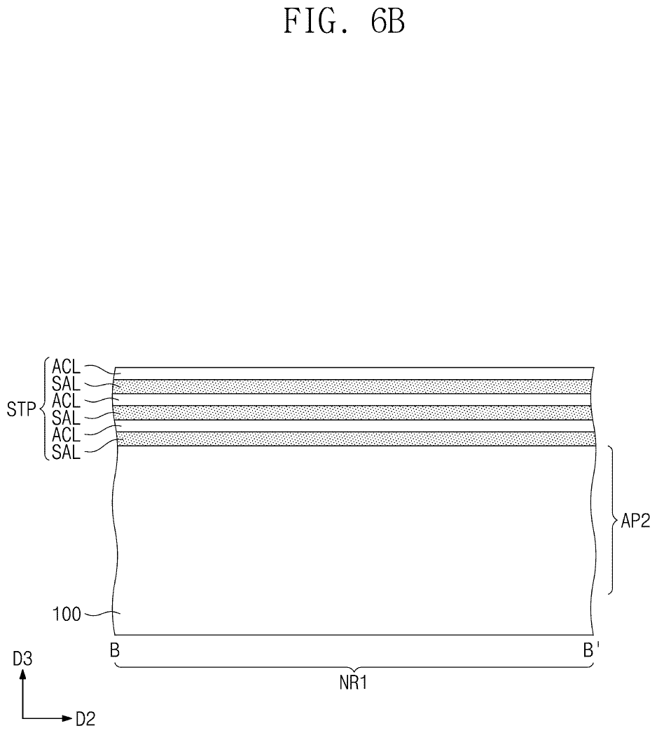

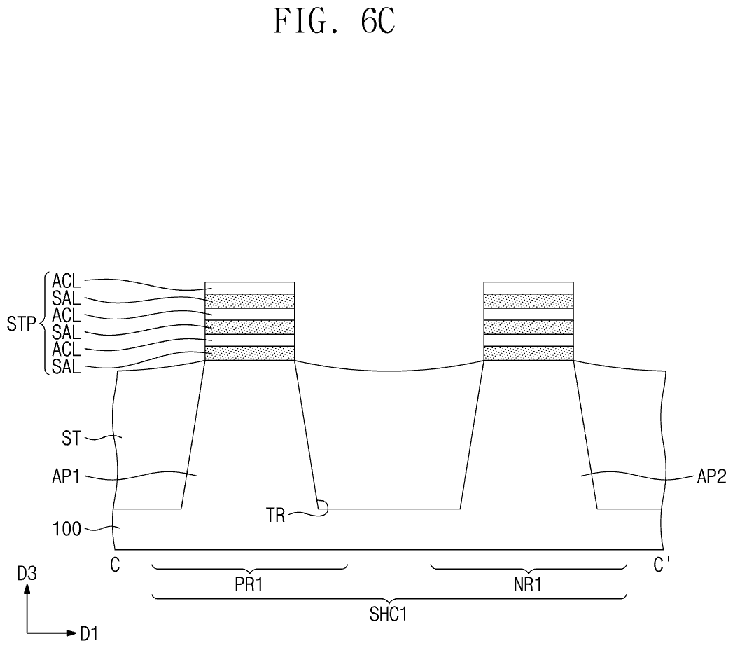

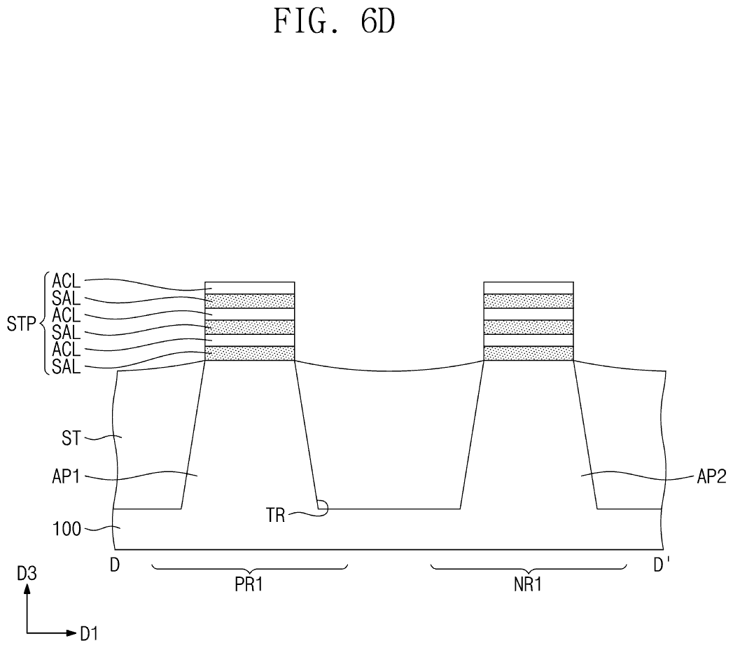

FIG. 6A to 17D are diagrams illustrating a method of fabricating a semiconductor device, according to an embodiment of the inventive concept. FIGS. 6A, 7A, 8A, 9A, 10A, 11A, 12, 13A, 14A, 15A, 16A, and 17A are sectional views corresponding to the line A-A′ of FIG. 4. FIGS. 6B, 7B, 8B, 9B, 10B, 11B, 12B, 13B, 14B, 15B, 16B, and 17B are sectional views corresponding to the line B-B′ of FIG. 4. FIGS. 6C, 7C, 8C, 9C, 10C, 11C, 12C, 13C, 14C, 15C, 16C, and 17C are sectional views corresponding to the line C-C′ of FIG. 4. FIGS. 6D, 7D, 8D, 9D, 10D, 11D, 12D, 13D, 14D, 15D, 16D, and 17D are sectional views corresponding to the line D-D′ of FIG. 4. For concise description, an element previously described with reference to FIGS. 1 to 5D may be identified by the same reference number without repeating an overlapping description thereof.

Referring to FIGS. 6A to 6D, the substrate 100 having the first PMOSFET region PR1, the second PMOSFET region PR2, the first NMOSFET region NR1, and the second NMOSFET region NR2 may be provided. The first NMOSFET region NR1 and the first PMOSFET region PR1 may define the first single height cell SHC1, and the second NMOSFET region NR2 and the second PMOSFET region PR2 may define the second single height cell SHC2.

The first and second active patterns AP1 and AP2 may be formed by patterning the substrate 100. The first active pattern AP1 may be formed on each of the first and second PMOSFET regions PR1 and PR2. The second active pattern AP2 may be formed on each of the first and second NMOSFET regions NR1 and NR2.

In an embodiment, the formation of the first and second active patterns AP1 and AP2 may include forming a mask pattern on the substrate and etching the substrate 100 using the mask pattern as an etch mask. As a result of the etching process, the trench TR may be formed to define the first active pattern AP1 and the second active pattern AP2.

First sacrificial layers SAL and active layers ACL may be alternatingly stacked on the substrate 100 in the third direction D3 perpendicular to the top surface of the substrate 100. The first sacrificial layers SAL and the active layers ACL may be formed of or include at least one of silicon (Si), germanium (Ge), or silicon germanium (SiGe) and may be formed of different materials from each other. For example, the first sacrificial layers SAL may include silicon-germanium (SiGe), and the active layers ACL may include silicon (Si).

The device isolation layer ST may be formed to fill the trench TR. In detail, an insulating layer may be formed on the substrate 100 to cover the first and second active patterns AP1 and AP2 and stacking patterns STP. The device isolation layer ST may be formed by recessing the insulating layer to expose the stacking patterns STP.

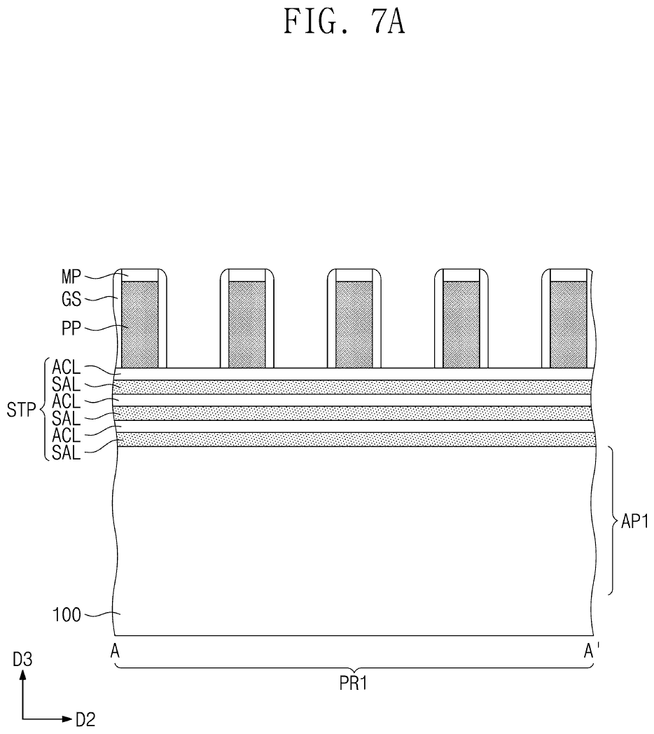

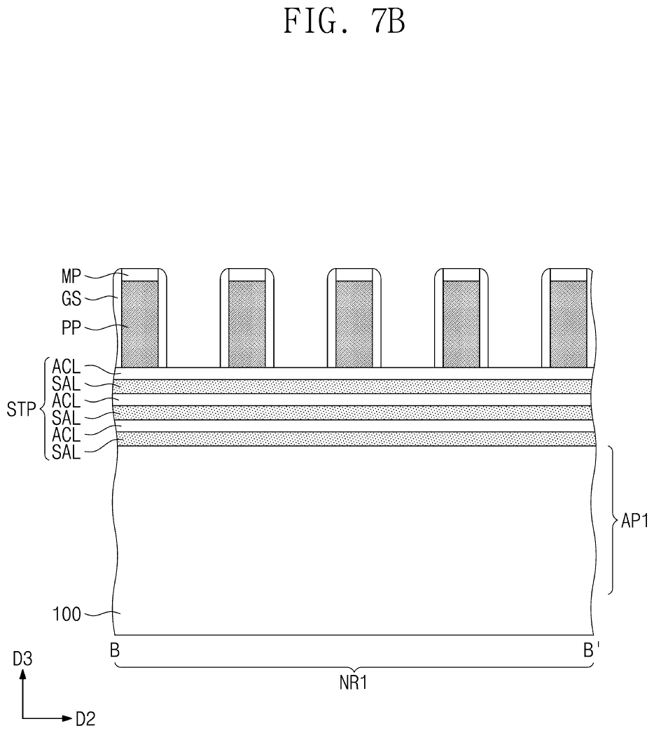

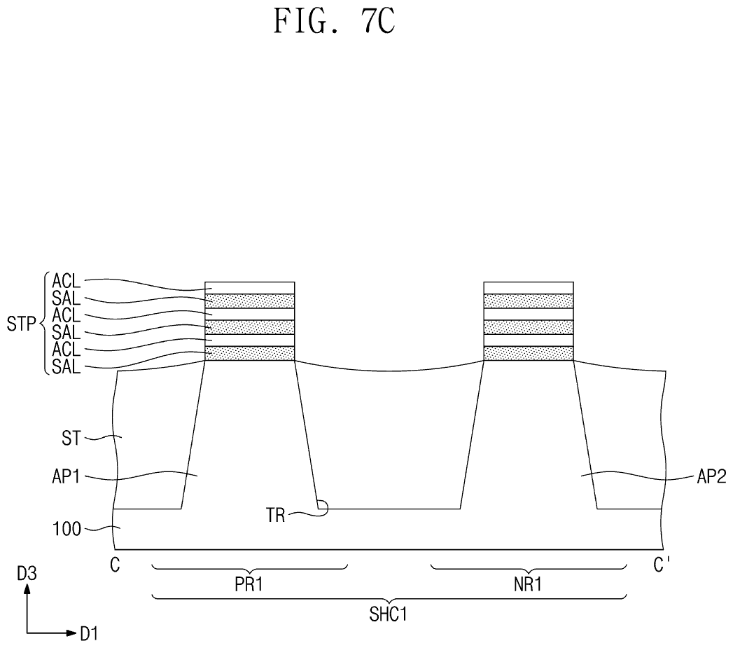

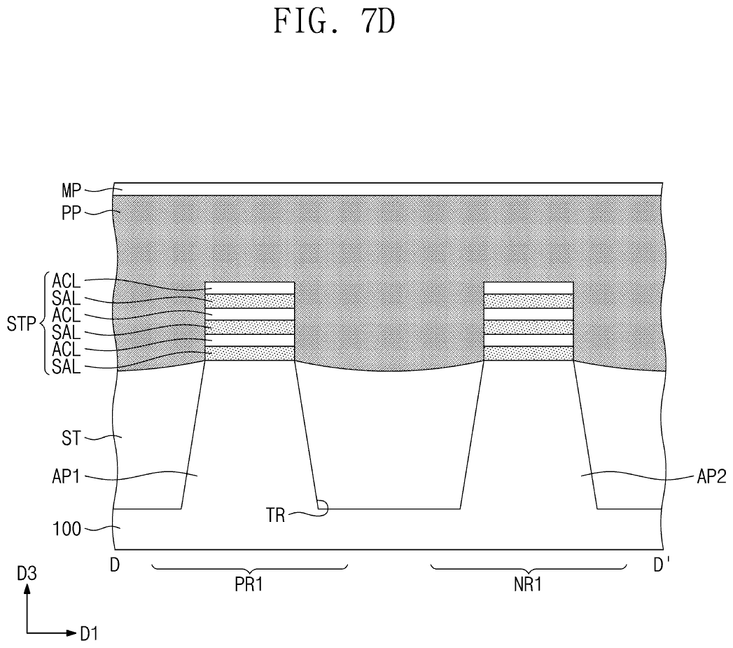

Referring to FIGS. 7A to 7D, sacrificial patterns PP may be formed on the substrate 100 to cross the stacking patterns STP. Each of the sacrificial patterns PP may be formed to have a line or bar shape extending in the first direction D1.

In detail, the formation of the sacrificial patterns PP may include forming a sacrificial layer on the substrate 100, forming first hard mask patterns MP on the sacrificial layer, and patterning the sacrificial layer using the first hard mask patterns MP as an etch mask. The sacrificial layer may be formed of or include polysilicon.

A pair of gate spacers GS may be formed on opposite side surfaces of each of the sacrificial patterns PP. The formation of the gate spacers GS may include conformally forming a gate spacer layer on the substrate 100 and anisotropically etching the gate spacer layer.

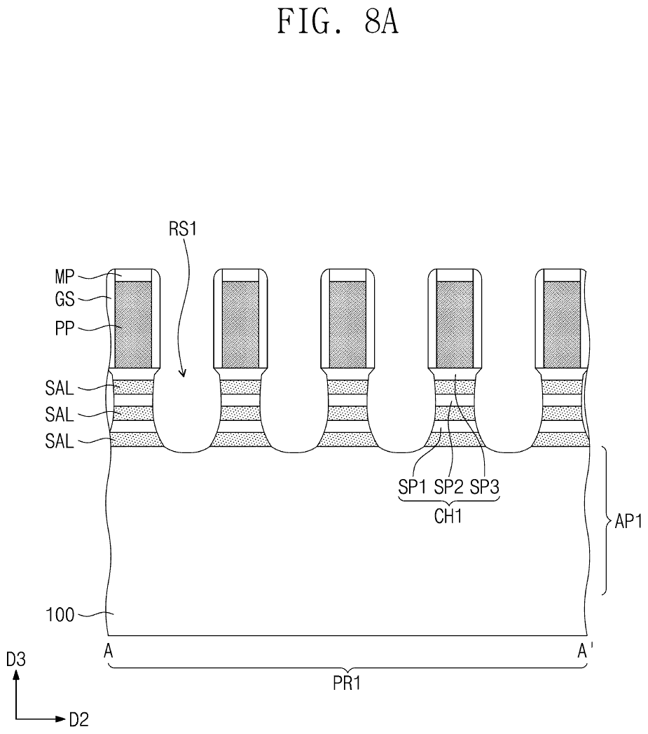

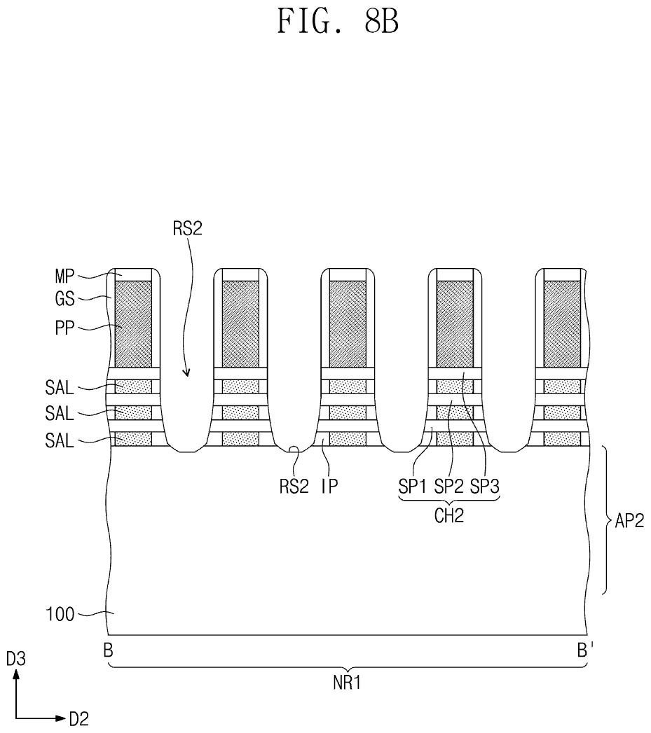

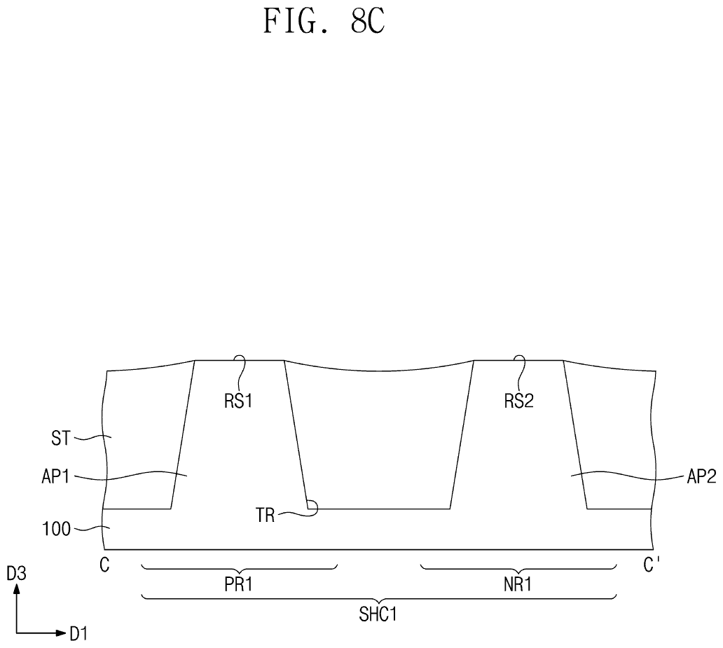

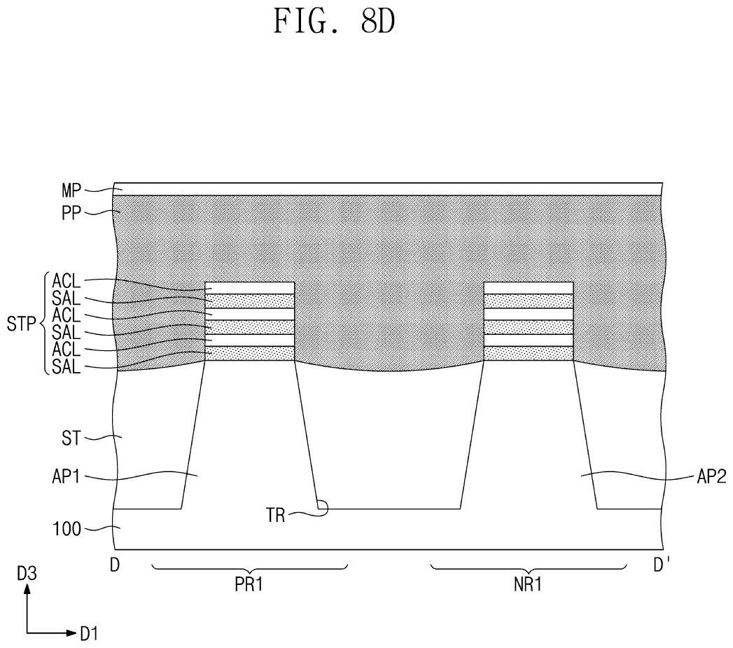

Referring to FIGS. 8A to 8D, first recesses RS1 may be formed in the stacking patterns STP on the first active pattern AP1. Second recesses RS2 may be formed in the stacking patterns STP on the second active pattern AP2. The device isolation layer ST at both sides of each of the first and second active patterns AP1 and AP2 may be recessed during the formation of the first and second recesses RS1 and RS2.

In detail, the first recesses RS1 may be formed by etching the stacking patterns STP on the first active pattern AP1 using the first hard mask patterns MP and the gate spacers GS as an etch mask. Each of the first recesses RS1 may be formed between a pair of the sacrificial patterns PP. The second recesses RS2 in the stacking pattern STP on the second active pattern AP2 may be formed by the same method as that for the first recesses RS1.

The first to third semiconductor patterns SP1, SP2, and SP3, which are sequentially stacked between adjacent ones of the first recesses RS1, may be formed from the active layers ACL. The first to third semiconductor patterns SP1, SP2, and SP3, which are sequentially stacked between adjacent ones of the second recesses RS2, may be formed from the active layers ACL. The first to third semiconductor patterns SP1, SP2, and SP3 between adjacent ones of the first recesses RS1 may constitute the first channel pattern CH1. The first to third semiconductor patterns SP1, SP2, and SP3 between the adjacent ones of the second recesses RS2 may constitute the second channel pattern CH2.

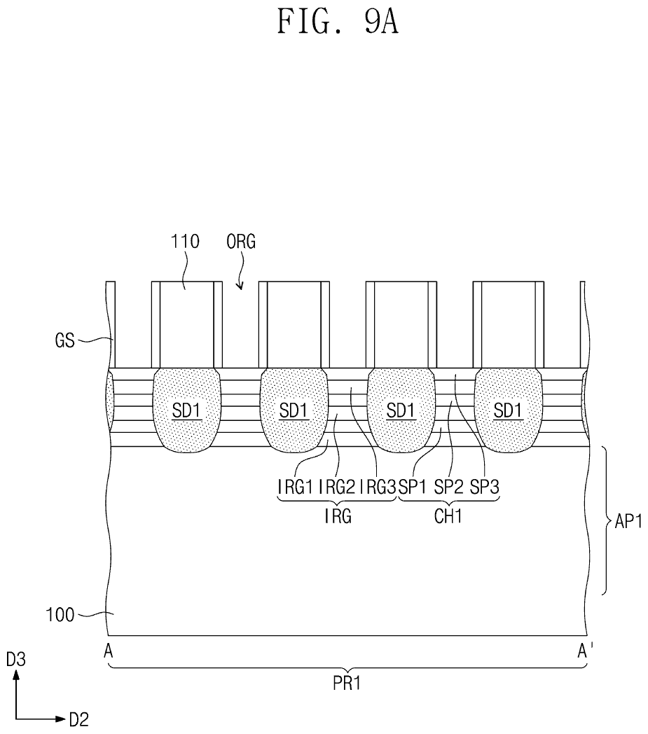

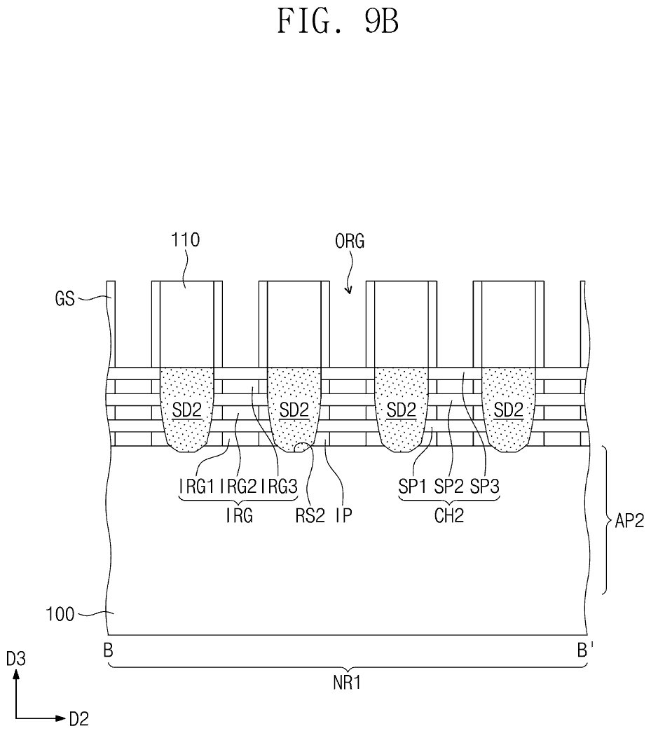

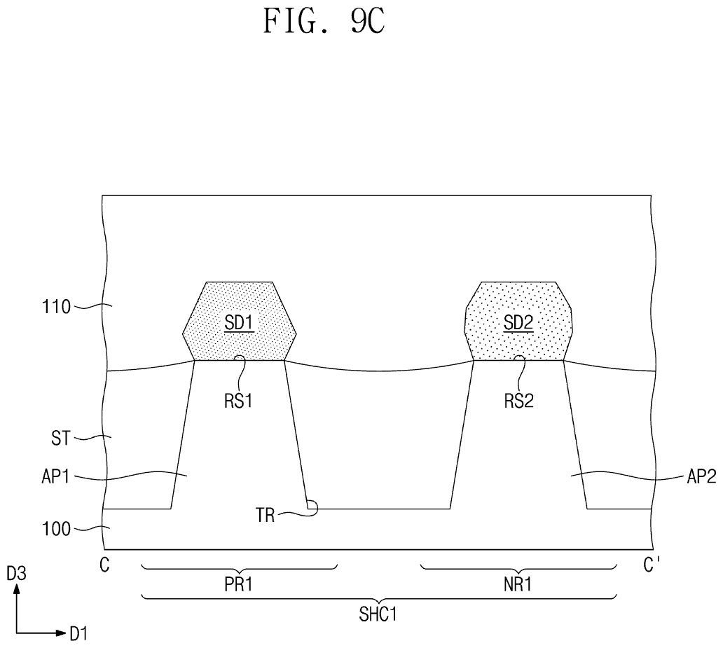

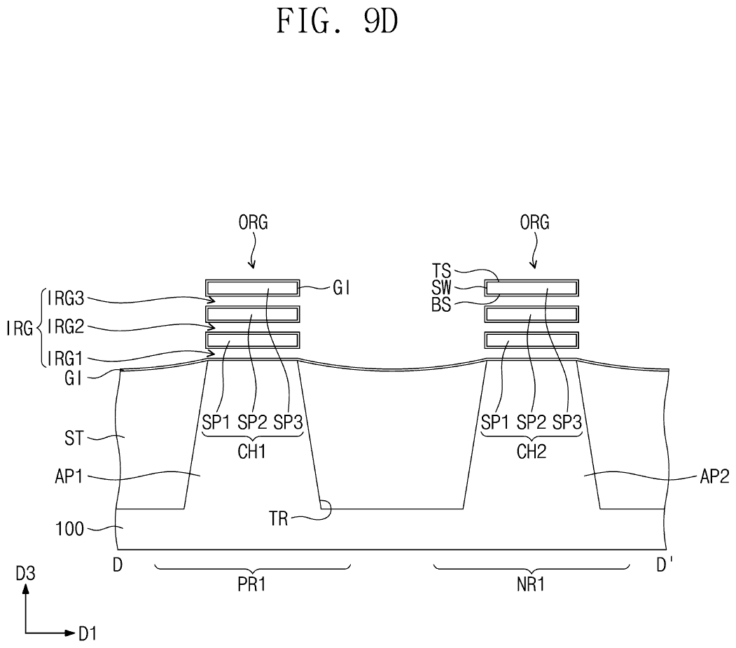

Referring to FIGS. 9A to 9D, the first source/drain pattern SD1 may be formed in the first recesses RS1. In detail, the first source/drain pattern SD1 may be formed by performing a first selective epitaxial growth (SEG) process using an inner surface of the first recess RS1 as a seed layer. The first SEG process may include a chemical vapor deposition (CVD) process or a molecular beam epitaxy (MBE) process.

The first source/drain pattern SD1 may be formed of or include a semiconductor material (e.g., SiGe) having a lattice constant larger than that of the substrate 100. During the first SEG process, impurities may be injected in an in-situ manner. In an embodiment, impurities may be injected into the first source/drain pattern SD1, after the formation of the first source/drain pattern SD1. The first source/drain pattern SD1 may be doped to have a first conductivity type (e.g., p-type).

The second source/drain patterns SD2 may be formed in the second recesses RS2, respectively. In detail, the second source/drain pattern SD2 may be formed by performing a second SEG process using an inner surface of the second recess RS2 as a seed layer. In an embodiment, the second source/drain pattern SD2 may include the same semiconductor material (e.g., Si) as the substrate 100. The second source/drain pattern SD2 may be doped to have a second conductivity type (e.g., n-type). The insulating pattern IP may be formed between the second source/drain pattern SD2 and each of the first sacrificial layers SAL.

The first interlayer insulating layer 110 may cover the first and second source/drain patterns SD1 and SD2, the first mask patterns MP, and the gate spacers GS. The first interlayer insulating layer 110 may be planarized until top surfaces of the sacrificial patterns PP are exposed. The planarization of the first interlayered insulating layer 110 may be performed using an etch-back process or a chemical-mechanical polishing (CMP) process. In an embodiment, the first hard mask patterns MP may be fully removed during the planarization process.

The exposed sacrificial patterns PP may be selectively removed. As a result of the removal of the sacrificial patterns PP, an outer region ORG may be formed to expose the first and second channel patterns CH1 and CH2. The removal of the sacrificial patterns PP may include a wet etching process which is performed using an etching solution capable of selectively etching polysilicon.

Inner regions IRG may be formed by selectively removing the first sacrificial layers SAL exposed through the outer region ORG. For example, a selective etching process may be performed to selectively remove the first sacrificial layers SAL and to leave the first to third semiconductor patterns SP1, SP2, and SP3. An etch recipe for the etching process may be chosen to etch a layer (e.g., a silicon germanium layer) having a relatively high germanium concentration, at a high etch rate.

The first sacrificial layers SAL on the first and second active patterns AP1 and AP2 may be removed during the etching process. The etching process may be a wet etching process. An etchant material, which is used in the etching process, may be chosen to quickly remove the sacrificial layers SAL having a relatively high germanium concentration.

Since the first sacrificial layers SAL are selectively removed, only the stack of the first to third semiconductor patterns SP1, SP2, and SP3 may be left on each of the first and second active patterns AP1 and AP2. Empty regions, which are formed by removing the first sacrificial layers SAL, may form the first to third inner regions IRG1, IRG2, and IRG3, respectively.

The gate insulating layer GI may be formed on the first to third semiconductor patterns SP1, SP2, and SP3 exposed. The gate insulating layer GI may be formed to enclose each of the first to third semiconductor patterns SP1, SP2, and SP3.

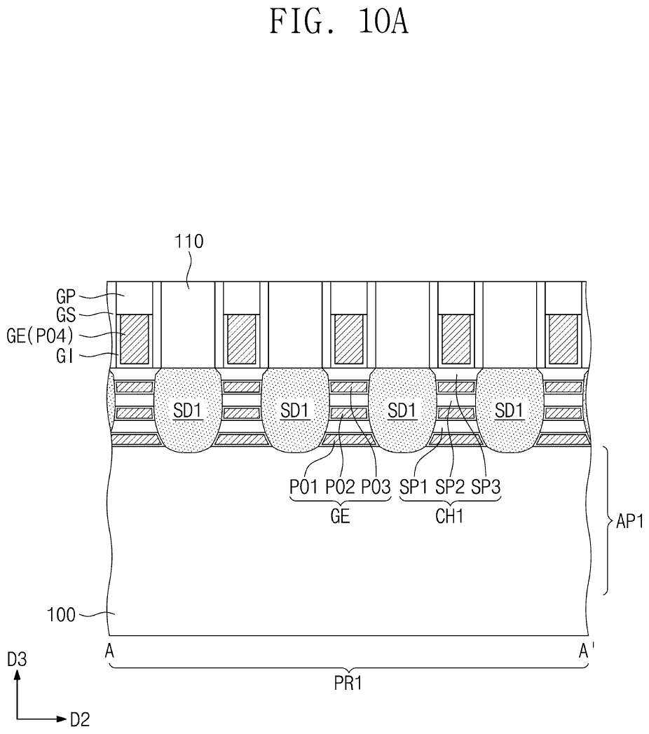

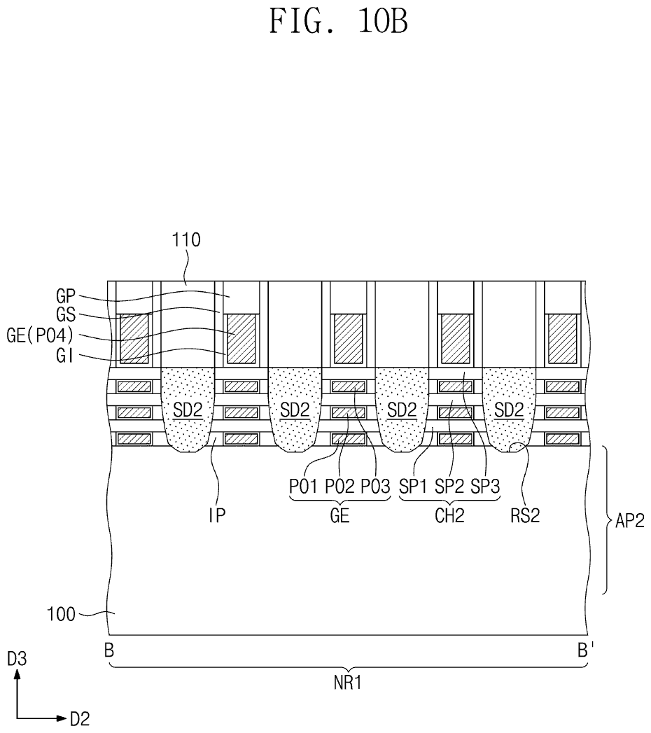

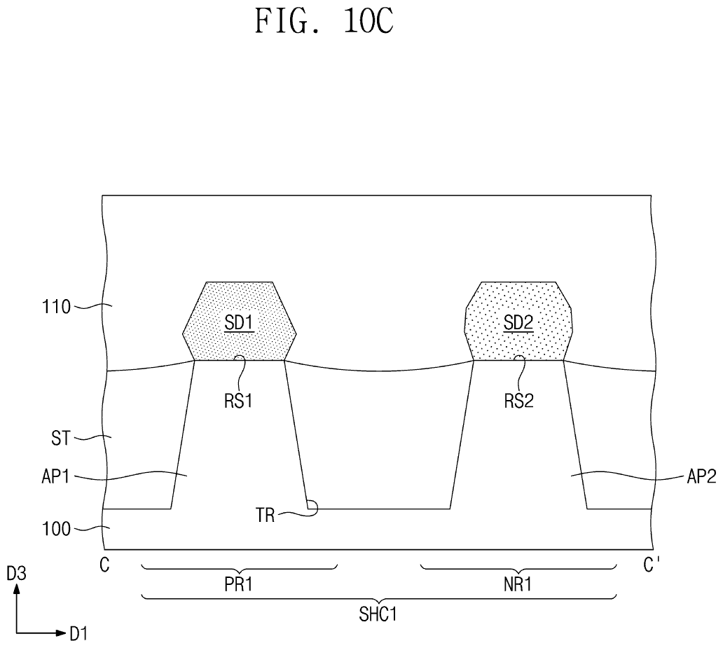

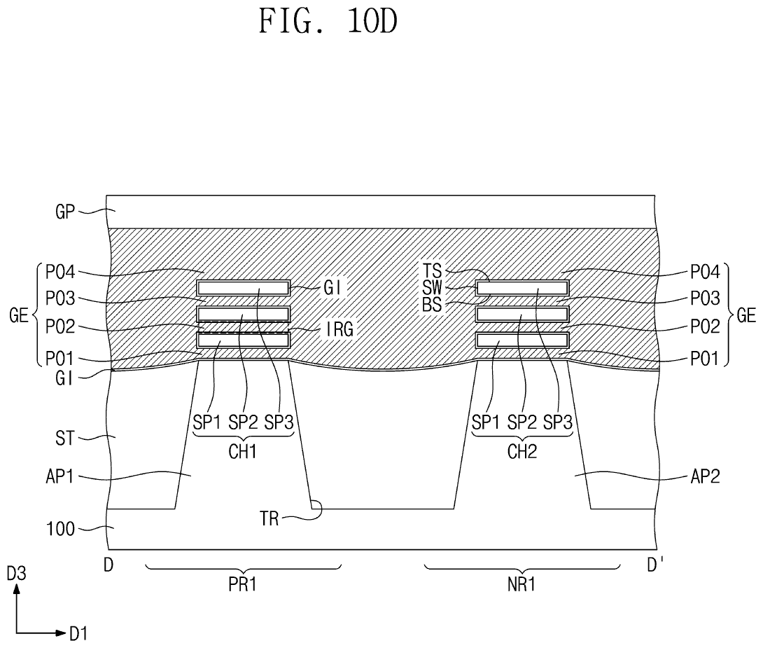

Referring to FIGS. 10A to 10D, the gate electrode GE may include the first to third portions PO1, PO2, and PO3, which are respectively formed in the first to third inner regions IRG1, IRG2, and IRG3, and the fourth portion PO4, which is formed in the outer region ORG. The gate electrode GE may be recessed to have a reduced height. The gate capping pattern GP may be formed on the recessed gate electrode GE. The gate cutting patterns CT may be disposed on a border, parallel to the second direction D2, of each of the first and second single height cells SHC1 and SHC2.

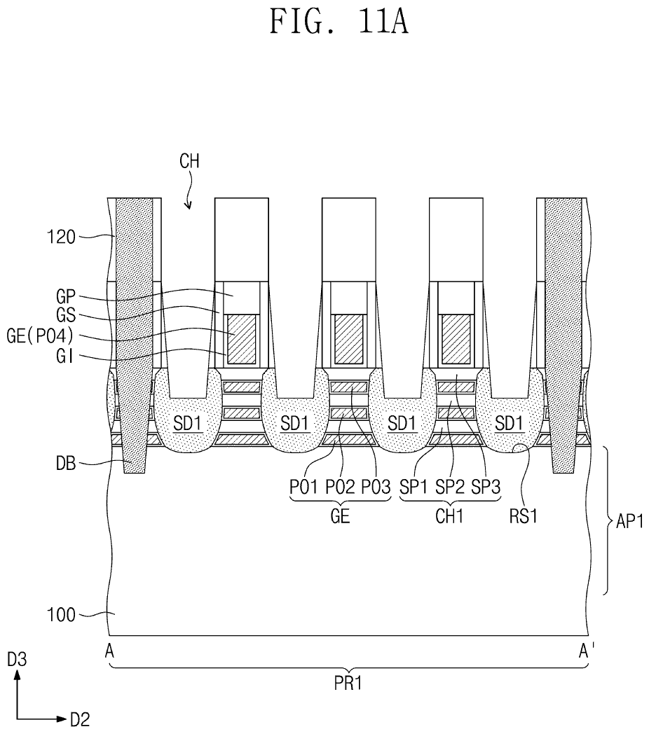

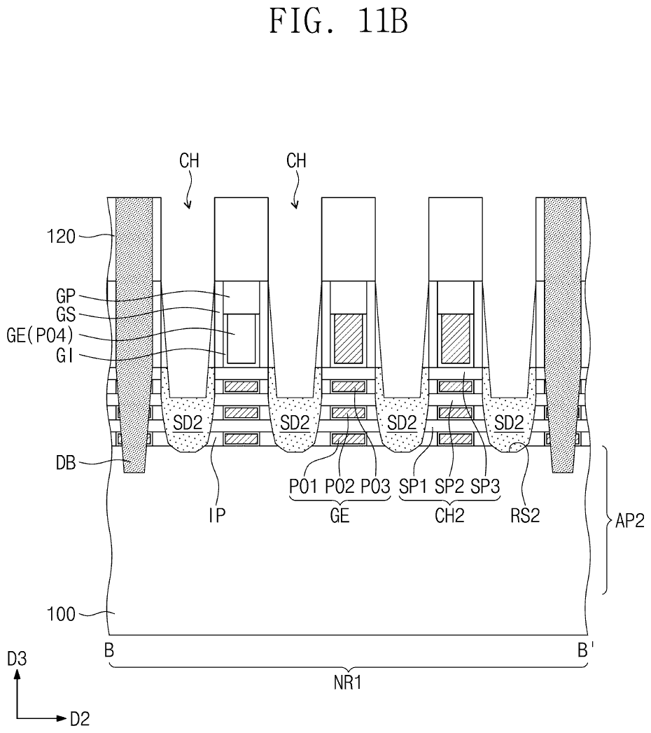

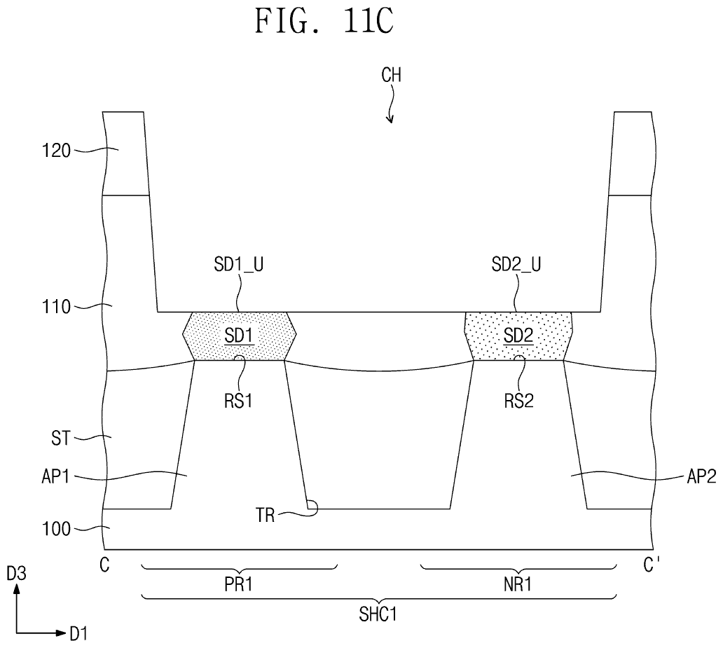

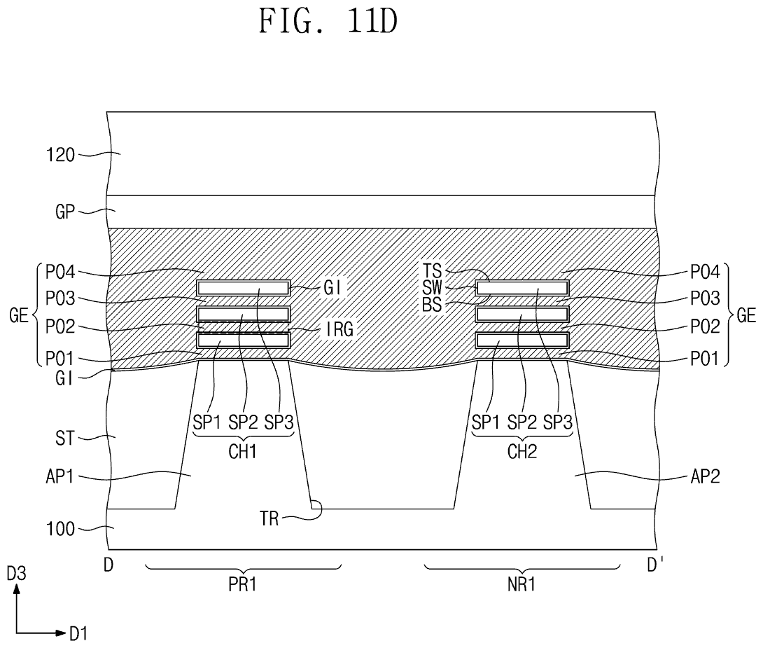

Referring to FIGS. 11A to 11D, the second interlayer insulating layer 120 may be formed on the first interlayer insulating layer 110 and the gate capping pattern GP. A pair of division structures DB may be formed on the first and second borders BD1 and BD2, respectively, of the first single height cell SHC1. The division structure DB may be extended in the first direction D1.

A first contact hole CH may be formed to penetrate the second and first interlayer insulating layers 120 and 110 and to expose top surfaces SD1_U and SD2_U of the first and second source/drain patterns SD1 and SD2. In an embodiment, the formation of the first contact hole CH may include forming a mask pattern on the second interlayer insulating layer 120 and etching the second and first interlayer insulating layers 120 and 110 using the mask pattern as an etch mask to expose the top surface SD1_U of the first source/drain pattern SD1 and/or the top surface SD2_U of the second source/drain pattern SD2.

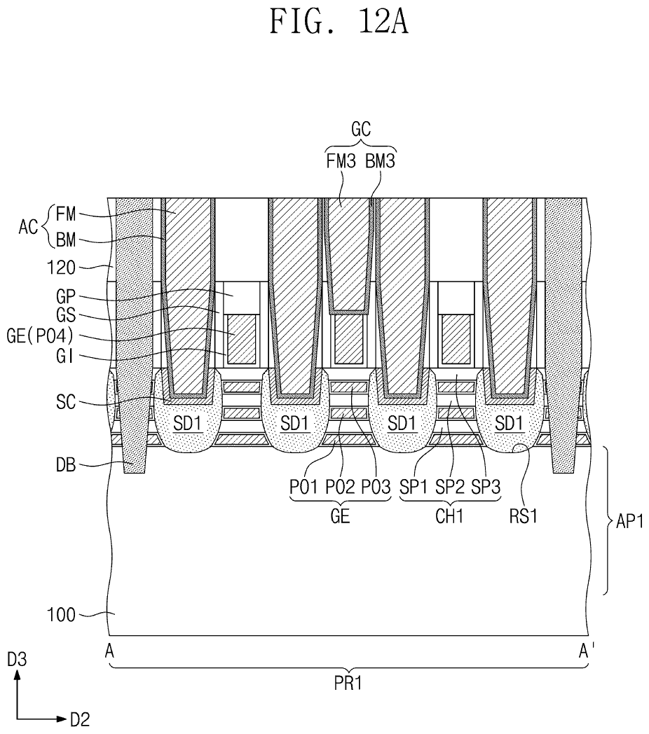

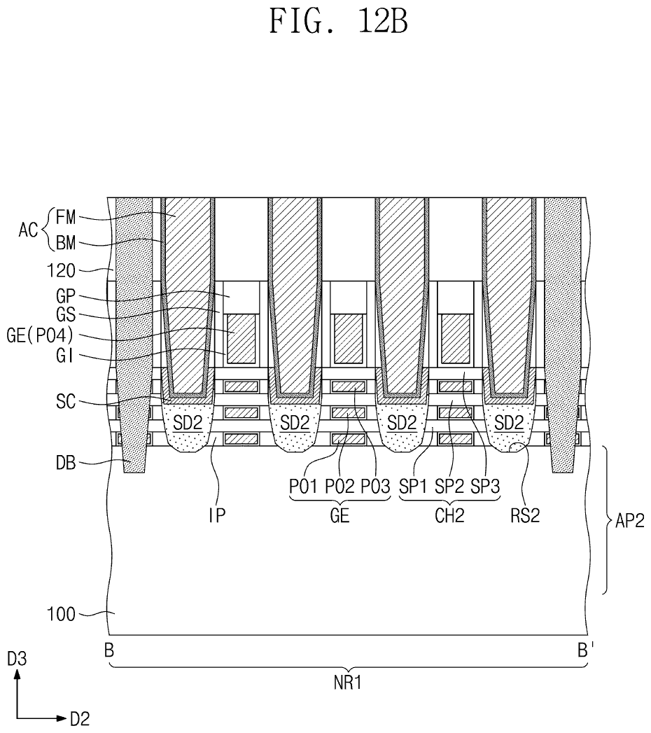

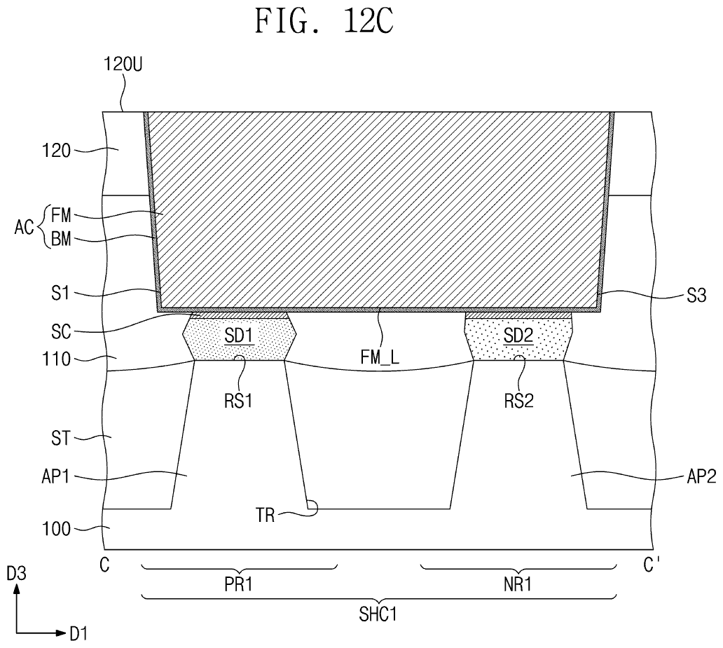

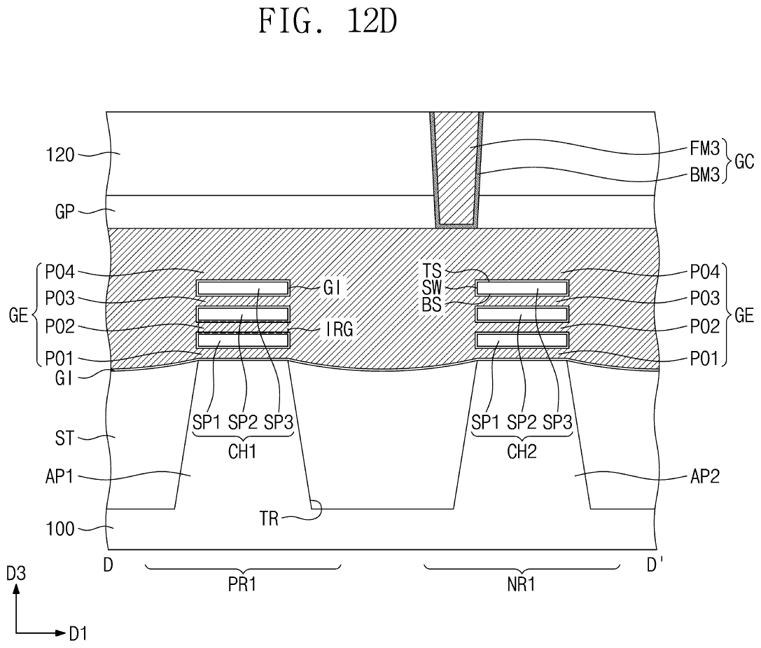

Referring to FIGS. 12A to 12D, the active contacts AC may be formed on the first and second source/drain patterns SD1 and SD2. The active contact AC may include a conductive pattern FM and a barrier pattern BM covering the conductive pattern FM. The conductive pattern FM may include side surfaces, which are opposite to each other in the first direction D1. The barrier pattern BM may cover the side surfaces of the conductive pattern FM and may cover a bottom surface FM_L of the conductive pattern FM. In an embodiment, the formation of the active contact AC may include forming a barrier layer to fill a portion of the first contact hole CH, forming a conductive layer on the barrier layer to fill the remaining portion of the first contact hole CH, and planarizing the conductive layer and the barrier layer to expose the top surface 120U of the second interlayer insulating layer 120.

The gate contact GC may be formed on the gate electrode GE to penetrate the second interlayer insulating layer 120 and the gate capping pattern GP. The gate contact GC may include the third conductive pattern FM3 and the third barrier pattern BM3. In an embodiment, the formation of the gate contact GC may include forming a mask pattern on the second interlayer insulating layer 120, etching the gate capping pattern GP and the second interlayer insulating layer 120 using the mask pattern as an etch mask to form an empty space exposing the top surface of the gate electrode GE, forming the third barrier pattern BM3 and the third conductive pattern FM3 to fill the empty space, and performing a planarization process to expose the top surface 120U of the second interlayer insulating layer 120.

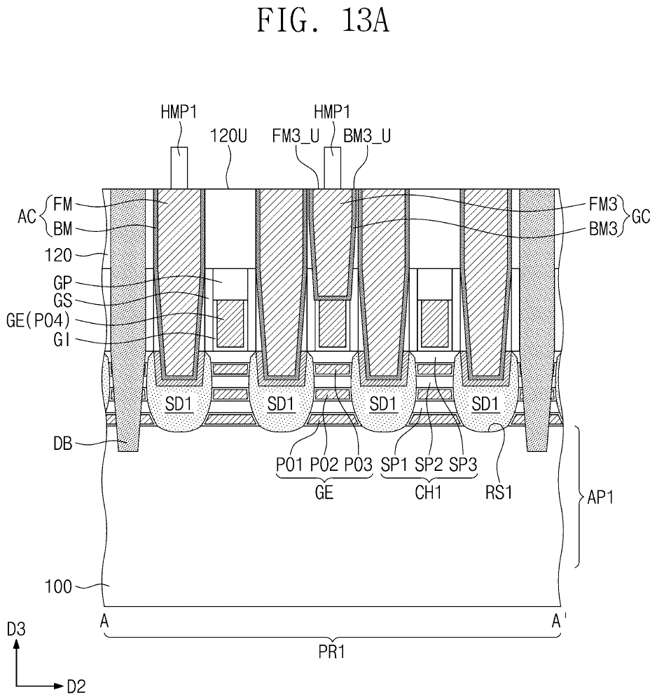

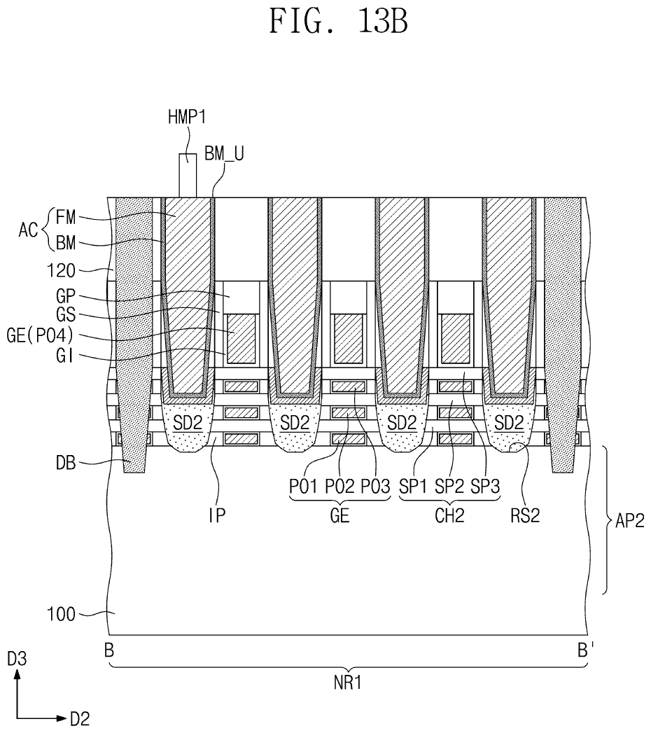

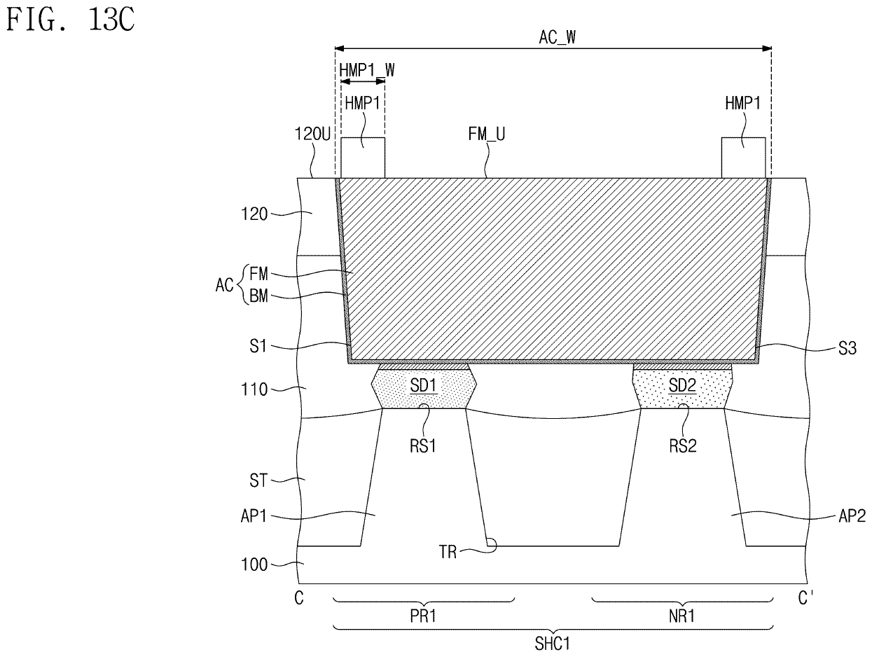

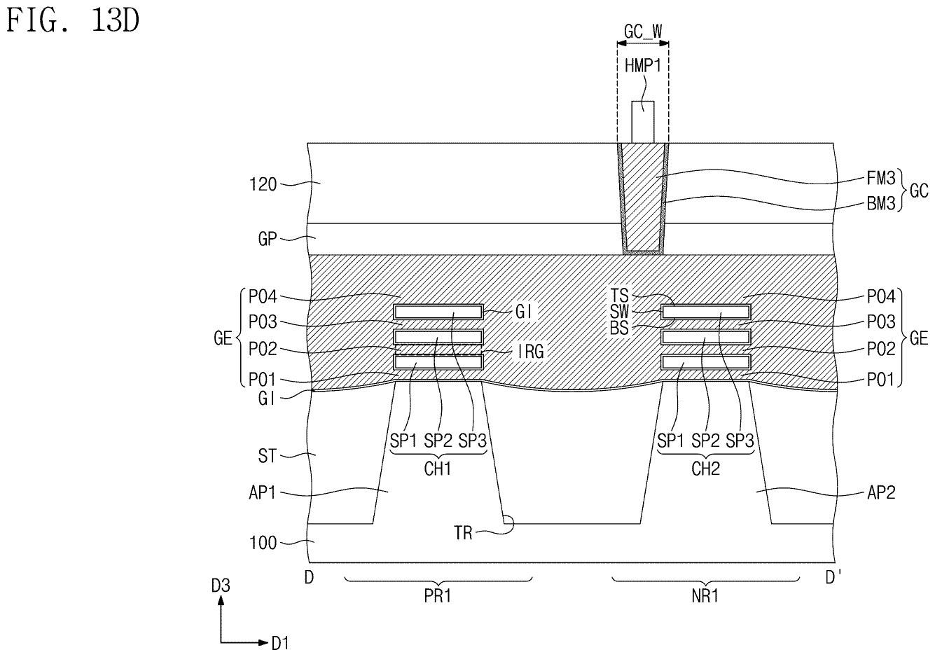

Referring to FIGS. 13A to 13D, first hard mask patterns HMP1 may be formed on the active contacts AC and the gate contact GC. Each of the first hard mask patterns HMP1 may be formed to expose the top surface 120U of the second interlayer insulating layer 120 and to expose a top surface of the active contact AC. Each of the first hard mask patterns HMP1 may be formed to expose a top surface BM_U of the barrier pattern BM and a top surface FM_U of the conductive pattern FM.

Each of the first hard mask patterns HMP1 may be formed to expose a top surface of the gate contact GC. Each of the first hard mask patterns HMP1 may be formed to expose a top surface BM3_U of the third barrier pattern BM3 and a top surface FM3_U of the third conductive pattern FM3.

A width HMP1_W of each of the first hard mask patterns HMP1 in the first direction D1 may be smaller than a width AC_W of each of the active contacts AC in the first direction D1. The width HMP1_W of each of the first hard mask patterns HMP1 in the first direction D1 may be smaller than a width GC_W of the gate contact GC in the first direction D1.

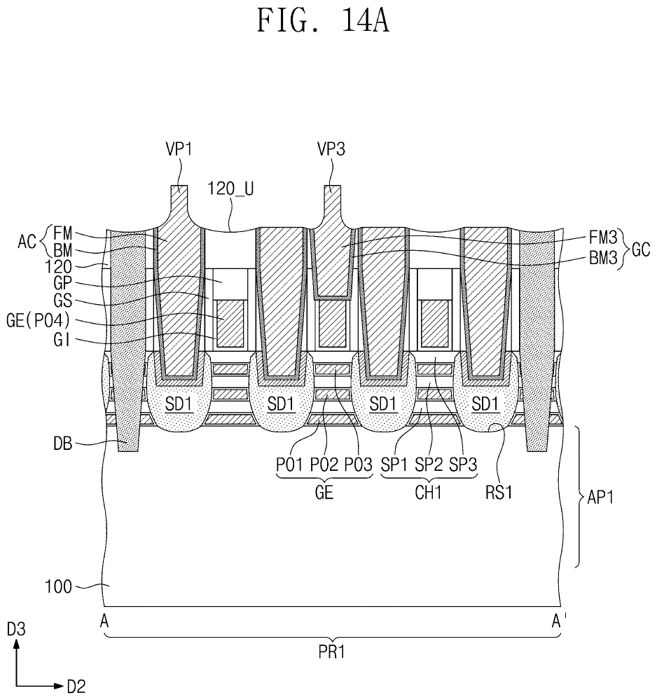

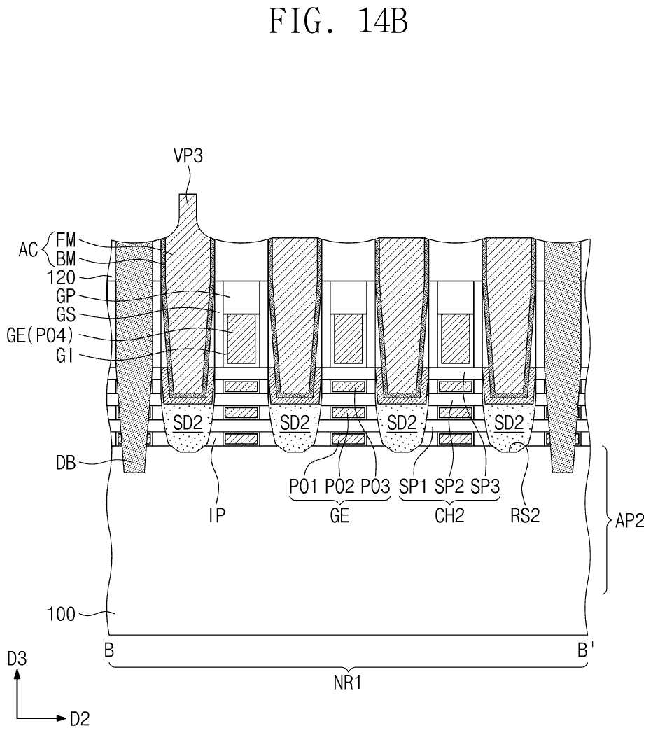

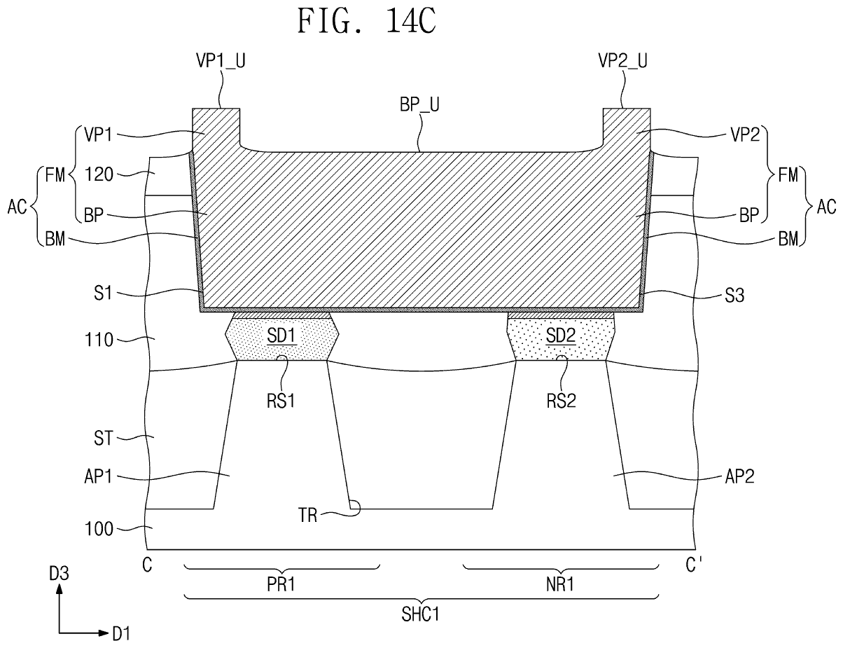

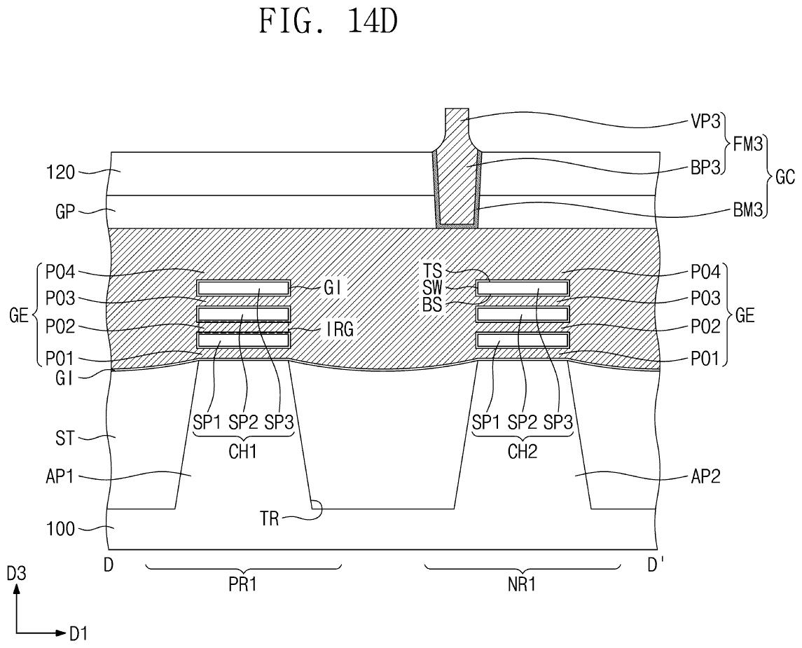

Referring to FIGS. 14A to 14D, a patterning process using the first hard mask patterns HMP1 may be performed to form a body portion BP and first and second via portions VP1 and VP2, which are extended from the body portion BP in the third direction D3. The first via portion VP1 may be formed on the first PMOSFET region PR1, and the second via portion VP2 may be formed on the first NMOSFET region NR1. In an embodiment, the formation of the body portion BP, the first via portion VP1, and the second via portion VP2 may include etching the second interlayer insulating layer 120 and the active pattern AC using the first hard mask patterns HMP1 as an etch mask.

In more detail, the barrier pattern BM and the conductive pattern FM, which are exposed by the first hard mask patterns HMP1, may be etched. Thus, at least a portion of an upper portion of the conductive pattern FM may be etched to form the first and second via portions VP1 and VP2. The barrier pattern BM and the second interlayer insulating layer 120 covering the upper portion of the conductive pattern FM may be partially removed by the etching process. The first and second via portions VP1 and VP2 may refer to remaining portions of the upper portion of the conductive pattern FM, and the body portion BP may refer to a lower portion of the conductive pattern FM.

In an embodiment, the first via portion VP1 and the body portion BP may form a single object, and the second via portion VP2 and the body portion BP may form a single object, i.e., the first via portion VP1 and the body portion BP may be formed to have no interface therebetween. The second via portion VP2 and the body portion BP may be formed to have no interface therebetween. Since the interface is not formed between the first and second via portions VP1 and VP2 and the body portion BP, the electric resistance of the active contact may be reduced. In this case, it may be possible to improve the electrical characteristics of the semiconductor device.

The first and second via portions VP1 and VP2 may be placed at a level higher than the second interlayer insulating layer 120 and thus may be exposed to the outside of the second interlayer insulating layer 120. A top surface of each of the first and second via portions VP1 and VP2 may be located at a level higher than the top surface 120U of the second interlayer insulating layer 120 and a top surface BP_U of the body portion BP. The second interlayer insulating layer 120 may cover the body portion BP. The top surface 120U of the second interlayer insulating layer 120 and the top surface BP_U of the body portion BP may be recessed toward the substrate 100 by the etching process.

The third body portion BP3 and the third via portion VP3 of the gate contact GC may be formed, and here, the third via portion VP3 may be extended from the third body portion BP3 in the third direction D3. In an embodiment, the formation of the third body portion BP3 and the third via portion VP3 may include etching the second interlayer insulating layer 120 and the gate capping pattern GP using the first hard mask patterns HMP1 as an etch mask. In more detail, the third barrier pattern BM3 and the third conductive pattern FM3, which are exposed by the first hard mask patterns HMP1, may be etched. Thus, at least a portion of an upper portion of the third conductive pattern FM3 may be etched to form the third via portion VP3. The third barrier pattern BM3 and the second interlayer insulating layer 120 covering the upper portion of the third conductive pattern FM3 may be partially removed by the etching process. The third via portion VP3 may refer to a remaining portion of the upper portion of the third conductive pattern FM3, and the third body portion BP3 may refer to a lower portion of the third conductive pattern FM3.

The third via portion VP3 may be placed at a level higher than the second interlayer insulating layer 120 and thus may be exposed to the outside of the second interlayer insulating layer 120. The second interlayer insulating layer 120 may cover the third body portion BP3. A top surface of the third body portion BP3 may be recessed to the substrate 100 by the etching process. In an embodiment, a top surface of each of the division structures DB may be recessed toward the substrate 100 by the etching process.

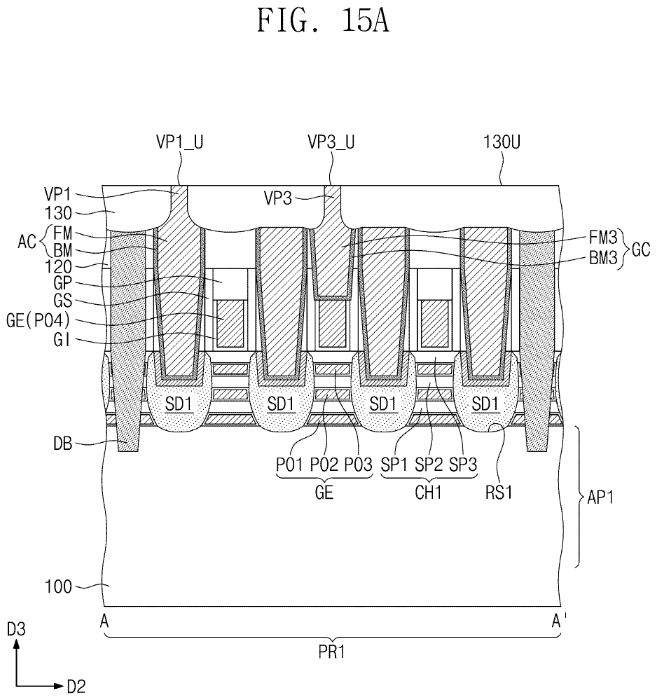

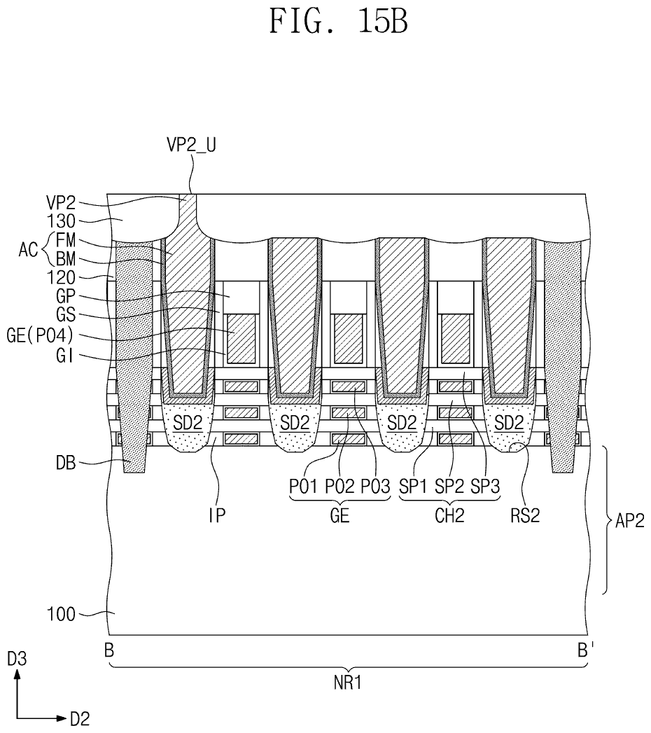

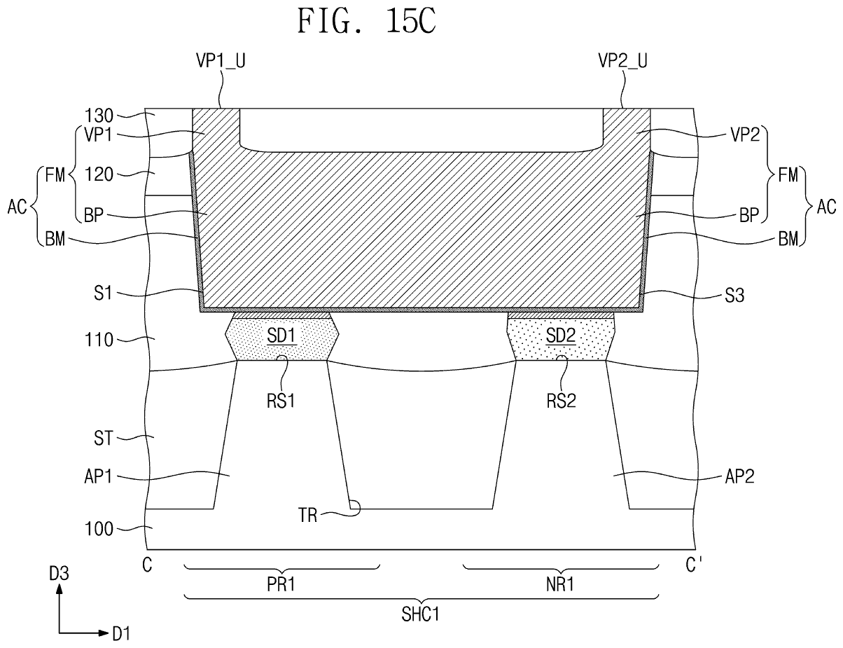

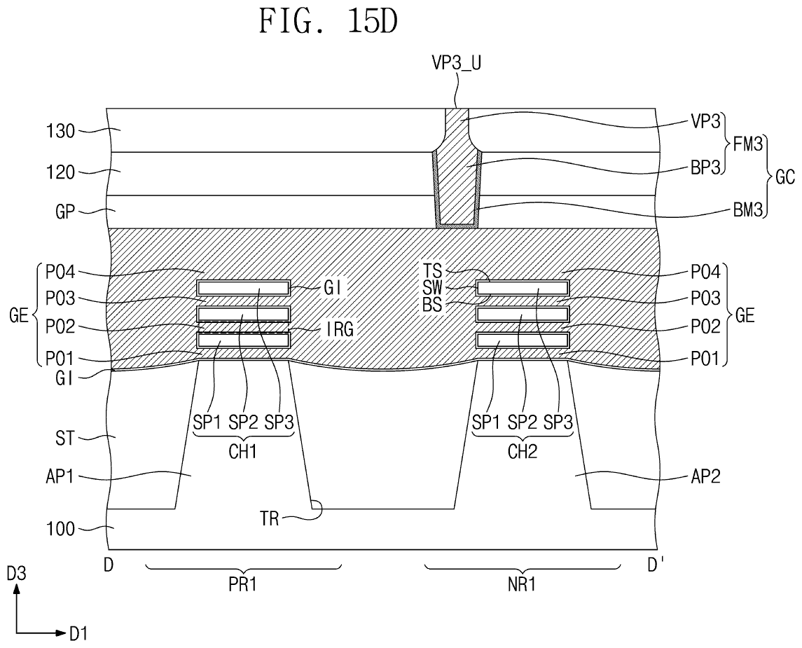

Referring to FIGS. 15A to 15D, the third interlayer insulating layer 130 may be formed on the second interlayer insulating layer 120. The third interlayer insulating layer 130 may cover the first, second, and third via portions VP1, VP2, and VP3. In an embodiment, the formation of the third interlayer insulating layer 130 may include depositing an insulating layer on the second interlayer insulating layer 120 and planarizing the insulating layer to expose the top surfaces VP1_U, VP2_U, and VP3_U of the first, second, and third via portions VP1, VP2, and VP3. As a result of the planarization process, the top surfaces VP1_U, VP2_U, and VP3_U of the first to third via portions VP1 to VP3 and the top surface 130U of the third interlayer insulating layer 130 may be located at the same level.

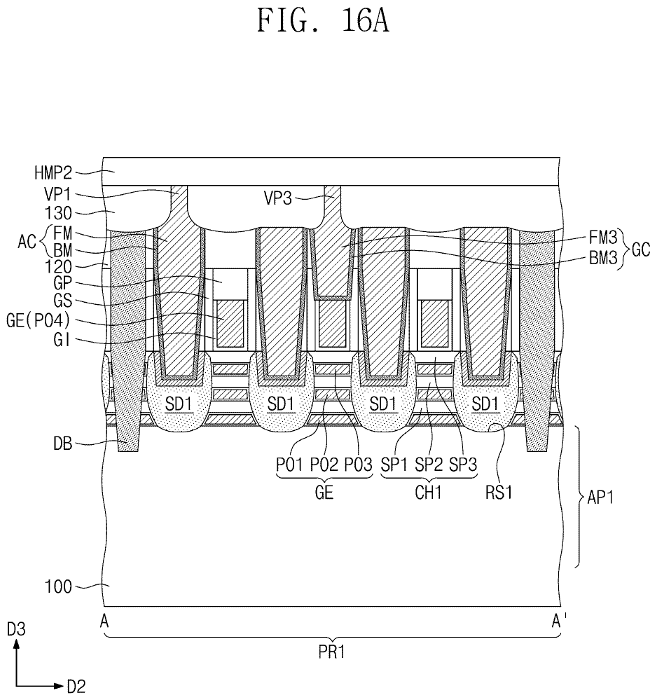

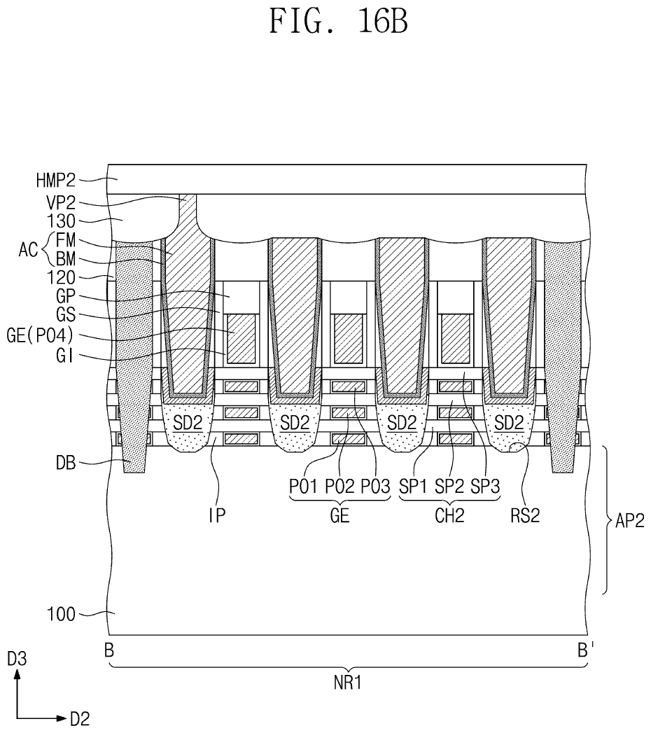

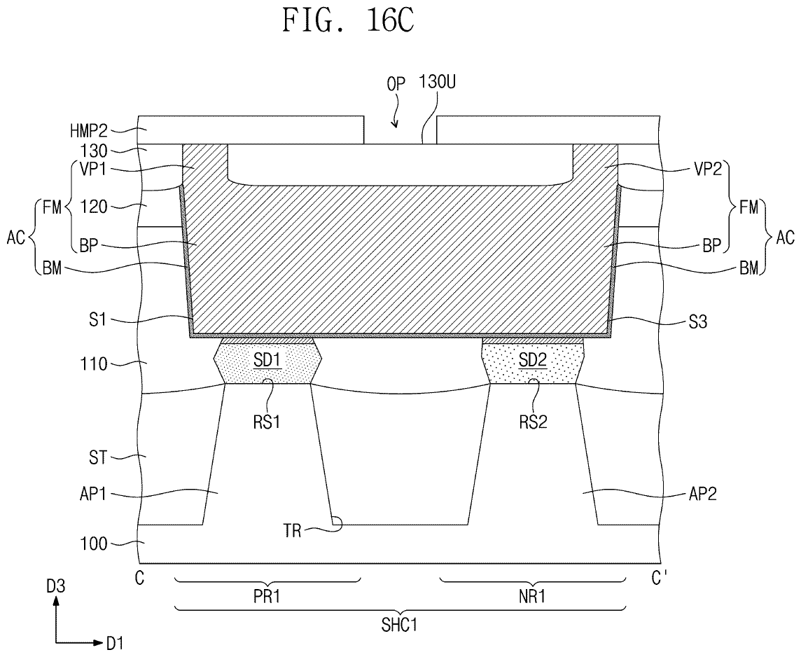

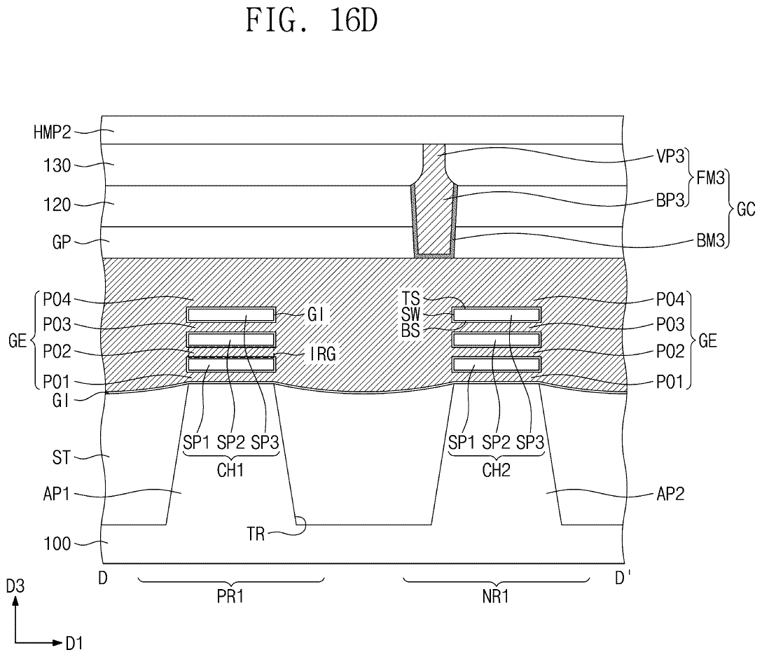

Referring to FIGS. 16A to 16D, a second hard mask pattern HMP2 may be formed on the third interlayer insulating layer 130. The second hard mask pattern HMP2 may be formed on the first and second via portions VP1 and VP2. The second hard mask pattern HMP2 may include an opening OP, and the opening OP may expose the top surface 130U of the third interlayer insulating layer 130. The opening OP may be vertically overlapped with the device isolation layer ST between the first and second source/drain patterns SD1 and SD2.

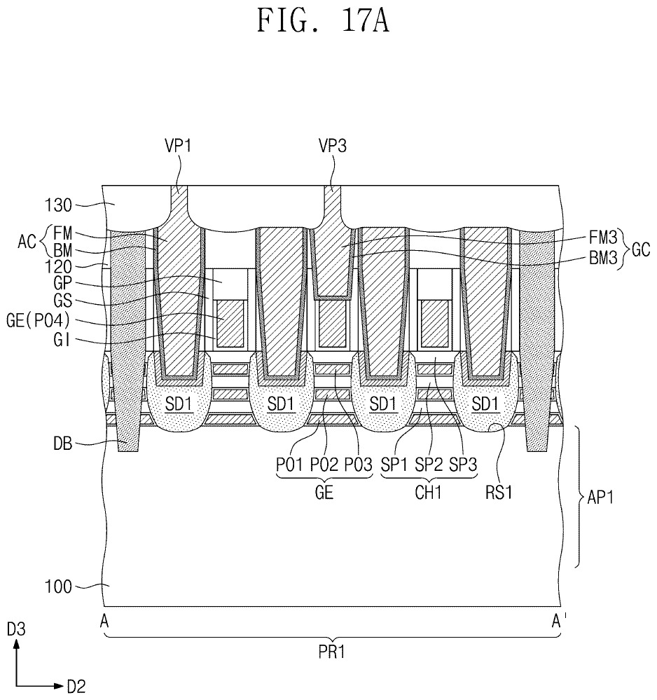

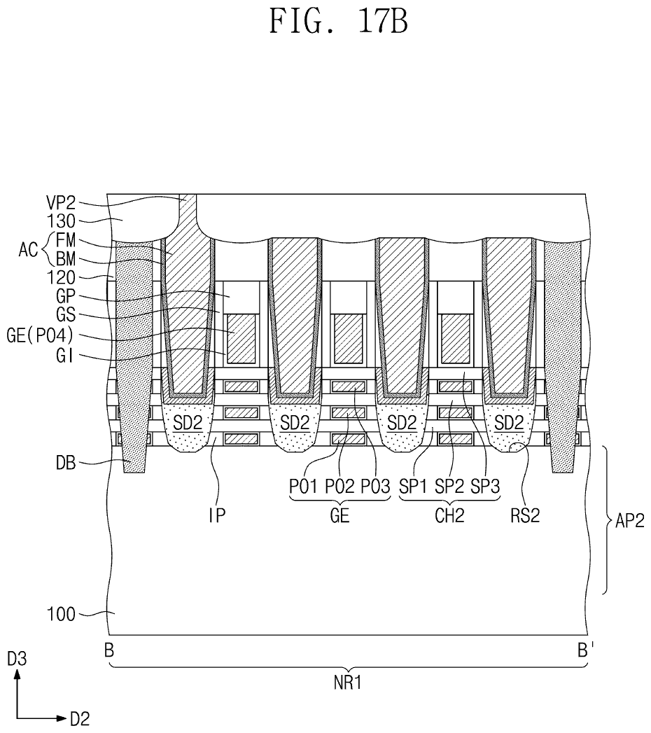

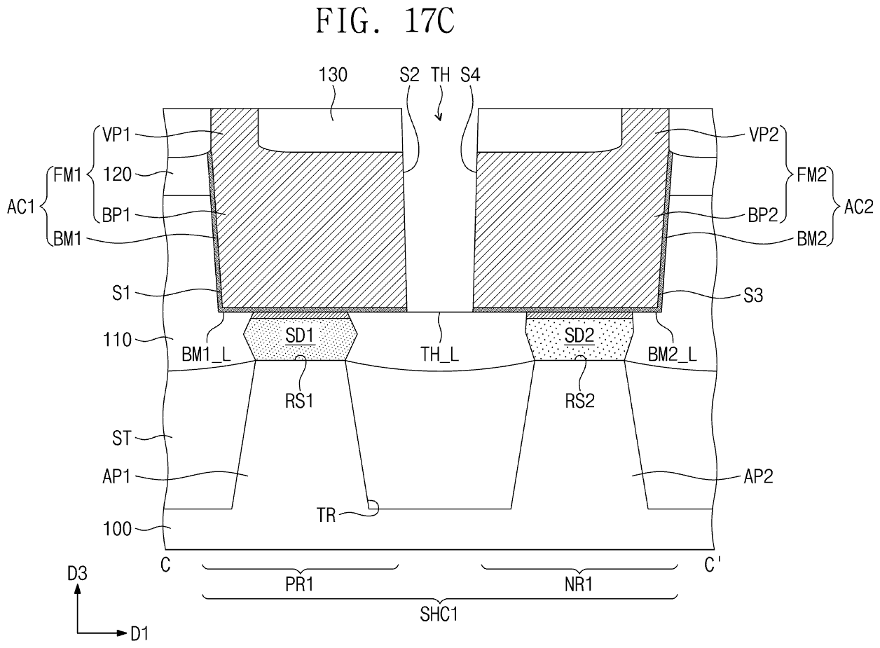

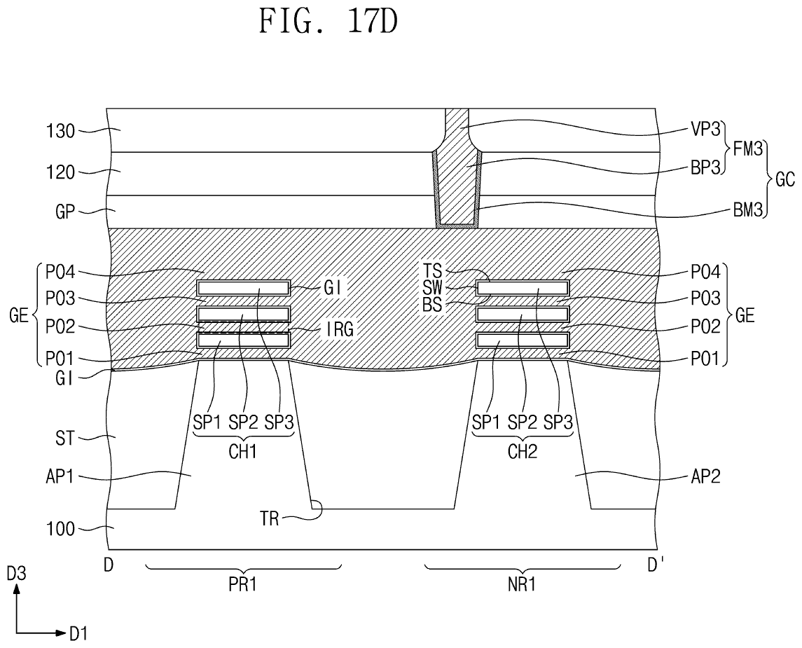

Referring to FIGS. 17A to 17D, a cutting hole TH may be formed to penetrate the first to third interlayer insulating layers 110, 120, and 130. The cutting hole TH may be formed to penetrate the active contact AC. The cutting hole TH may be formed to expose the first interlayer insulating layer 110 between the first and second source/drain patterns SD1 and SD2.

The active pattern AC may be divided into the first active pattern AC1 on the first source/drain pattern SD1 and the second active pattern AC2 on the second source/drain pattern SD2 by the cutting hole TH. The conductive pattern FM may be divided into the first and second conductive patterns FM1 and FM2 by the cutting hole TH. In more detail, the body portion BP of the conductive pattern FM may be divided into the first body portion BP1 and the second body portion BP2. The barrier pattern BM may be divided into the first barrier pattern BM1 and the second barrier pattern BM2 by the cutting hole TH.

The first active contact AC1 may include the first conductive pattern FM1 and the first barrier pattern BM1. The first conductive pattern FM1 may include the first body portion BP1 and the first via portion VP1. The first conductive pattern FM1 may include the first and second side surfaces S1 and S2, which are opposite to each other in the first direction D1. The first barrier pattern BM1 may cover the first side surface S1 and the bottom surface of the first conductive pattern FM1. The second side surface S2 of the first conductive pattern FM1 may be exposed by the cutting hole TH.

The second active contact AC2 may include the second conductive pattern FM2 and the second barrier pattern BM2. The second conductive pattern FM2 may include the second body portion BP2 and the second via portion VP2. The second conductive pattern FM2 may include the third and fourth side surfaces S3 and S4, which are opposite to each other in the first direction D1. The second barrier pattern BM2 may cover the third side surface S3 and the bottom surface of the second conductive pattern FM2. The fourth side surface S4 of the second conductive pattern FM2 may be exposed by the cutting hole TH.

A bottom surface TH_L of the cutting hole TH may be located at a level, which is equal to or lower than a bottom surface BM1_L of the first barrier pattern BM1. The bottom surface TH_L of the cutting hole TH may be located at a level, which is equal to or lower than a bottom surface BM2_L of the second barrier pattern BM2. In an embodiment, the formation of the cutting hole TH may include etching the third interlayer insulating layer 130, the active contact AC, and the first interlayer insulating layer 110 using the second hard mask pattern HMP2 as an etch mask.

Referring back to FIGS. 4 to 5D, the cutting pattern AT may be formed between the first active contact AC1 and the second active contact AC2. The cutting pattern AT may be in contact with the second side surface S2 of the first conductive pattern FM1 and the fourth side surface S4 of the second conductive pattern FM2.

The top surface AT_U of the cutting pattern AT may be located at the same level as the top surface 130U of the third interlayer insulating layer 130, the top surface VP1_U of the first via portion VP1, and the top surface VP2_U of the second via portion VP2. The top surface AT_U of the cutting pattern AT may be located at a level higher than the top surface BP1_U of the first body portion BP1 and the top surface BP2_U of the second body portion BP2. The top surface AT_U of the cutting pattern AT may be located at a level higher than the top surface 120U of the second interlayer insulating layer 120. The cutting pattern AT may be provided to penetrate the third, second, and first interlayer insulating layers 130, 120 and 110. The bottom surface AT_L of the cutting pattern AT may be located at a level, which is equal to or lower than the bottom surface of the first active contact AC1 and the bottom surface of the second active contact AC2. The width AT_W of the cutting pattern AT in the first direction D1 may range from 15nm to 20 nm.

The cutting pattern AT may include a low-k dielectric material. In more detail, the dielectric constant of the cutting pattern AT may be lower than those of the first interlayer insulating layer 110, the second interlayer insulating layer 120, and/or the third interlayer insulating layer 130. The cutting pattern AT may be formed of or include, for example, SiOC. In an embodiment, the formation of the cutting pattern AT may include filling the cutting hole TH with an insulating material and planarizing the insulating material to expose the top surfaces of the third interlayer insulating layer 130 and the first, second, and third via portions VP1, VP2, and VP3.

In an embodiment, the second side surface S2 of the first conductive pattern FM1 may be in contact with the cutting pattern AT, and the fourth side surface S4 of the second conductive pattern FM2 may be in contact with the cutting pattern AT. That is, a side surface of each of the first and second conductive patterns FM1 and FM2 may not be enclosed by either the first or second barrier pattern BM1 or BM2. Since an area of each of the first and second conductive patterns FM1 and FM2 is increased, the resistance of the first and second conductive patterns FM1 and FM2 may be lowered. As a result, the semiconductor device with improved electrical characteristics may be provided.

Furthermore, the cutting pattern AT may include a low-k dielectric material, and in this case, it may be possible to reduce a parasitic capacitance between adjacent ones of the active contacts. As a result, the semiconductor device with improved electrical characteristics may be provided.

In addition, since the cutting pattern AT is formed after the formation of the active contact AC, it may be possible to secure a sufficiently large margin in the process of forming the active contact AC. Thus, it may be possible to prevent a process failure (i.e., a not-open issue) where the top surface of the first or second source/drain pattern SD1 or SD2 is not exposed. In other words, it may be possible to increase the reliability in a process of fabricating a semiconductor device.

A fourth interlayer insulating layer may be formed on the third interlayer insulating layer 130. The first power line M1_R1, the second power line M1_R2, and the first interconnection lines M1_I may be formed in the fourth interlayer insulating layer. The fifth interlayer insulating layer 150 may be formed on the fourth interlayer insulating layer. The second interconnection lines M2_I and the connection vias CV may be formed in the fifth interlayer insulating layer 150.

According to an embodiment of the inventive concept, an active contact may include a body portion and a via portion, which are provided to form a single object, i.e., a unitary element free of observable interfaces between portions thereof. In other words, there may be no interface between the body portion and the via portion, and in this case, the electric resistance of the active contact may be reduced. As a result, the semiconductor device with improved electrical characteristics may be provided.

In addition, the active contact may include a conductive pattern whose side surface is in contact with a cutting pattern. That is, the side surface of the conductive pattern may not be enclosed by or may be free of a barrier pattern thereon. In this case, it may be possible to increase the area of the conductive pattern and thereby to reduce the electric resistance of the conductive pattern. As a result, the semiconductor device with improved electrical characteristics may be provided.

Furthermore, according to an embodiment of the inventive concept, the cutting pattern may be formed after the formation of the active contact. Thus, a material for the cutting pattern may be freely chosen. For example, the cutting pattern may include a low-k dielectric material, and in this case, it may be possible to reduce a parasitic capacitance between adjacent ones of the active contacts. As a result, the semiconductor device with improved electrical characteristics may be provided.

In addition, since the cutting pattern is formed after the formation of the active contact, it may be possible to secure a sufficiently large margin in a process of forming the active contact. Thus, it may be possible to prevent a process failure, in which a top surface of a source/drain pattern is not opened. In other words, it may be possible to increase the reliability in a process of fabricating a semiconductor device.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section.

Thus, a first element, component, region, layer or section described below could be termed a second element, component, region, layer or section, without departing from the spirit and scope of the present disclosure.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

Components or layers described with reference to being “sequential” or “sequentially stacked” in a particular direction or manner may be at layered, adjoined, proximate, orientated, or otherwise arranged with respect to each other to achieve the illustrated or contemplated relativity, optionally with other components, layers, etc. therebetween. Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device. The term “in contact with” may be used to describe elements that are free of intervening elements therebetween.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate including a first active pattern and a second active pattern spaced apart from each other in a first direction;
a first source/drain pattern on the first active pattern;
a second source/drain pattern on the second active pattern;
a first active contact on the first source/drain pattern;
a second active contact on the second source/drain pattern;
a cutting pattern between the first and second active contacts;
wherein each of the first and second active contacts comprises: a conductive pattern having a first side surface and a second side surface opposite to each other in the first direction; and a barrier pattern on the first side surface of the conductive pattern and on a bottom surface of the conductive pattern;
wherein the cutting pattern is in contact with the second side surface of the conductive pattern of each of the first and second active contacts; and
wherein the first direction is parallel to a top surface of the substrate.

2. The semiconductor device of claim 1, wherein:
the conductive pattern of the first active contact comprises:
a first body portion on the first source/drain pattern; and
a first via portion extended from the first body portion in a third direction;
wherein a top surface of the first body portion is recessed toward the substrate;
and the third direction is perpendicular to the top surface of the substrate.

3. The semiconductor device of claim 2, further comprising:
a first interlayer insulating layer on the substrate and on the first and second source/drain patterns;
a second interlayer insulating layer on the first interlayer insulating layer;
wherein the first body portion of the conductive pattern penetrates the first and second interlayer insulating layers; and
a top surface of the second interlayer insulating layer is recessed toward the substrate.

4. The semiconductor device of claim 2, wherein a top surface of the cutting pattern is farther from the substrate than a top surface of the first body portion of the conductive pattern of the first active contact.

5. The semiconductor device of claim 2, wherein a top surface of the cutting pattern is coplanar with a top surface of the first via portion of the conductive pattern.

6. The semiconductor device of claim 2, wherein the first body portion and the first via portion of the conductive pattern form a single object.

7. The semiconductor device of claim 2, further comprising a first metal layer on the first active contact, wherein the first metal layer comprises a metal line and the metal line is electrically connected to the first active contact through the first via portion.

8. The semiconductor device of claim 1, wherein a width of the cutting pattern in the first direction ranges from 15 nm to 20 nm.

9. The semiconductor device of claim 1, further comprising:
a first interlayer insulating layer on the substrate and on the first source/drain pattern and the second source/drain pattern; and
wherein a dielectric constant of the cutting pattern is lower than a dielectric constant of the first interlayer insulating layer.

10. A semiconductor device, comprising:
a substrate including a first active pattern and a second active pattern, where the first and second active patterns are spaced apart from each other in a first direction parallel to a top surface of the substrate;
a first source/drain pattern on the first active pattern;
a second source/drain pattern on the second active pattern;
a first active contact on the first source/drain pattern;
a second active contact on the second source/drain pattern;
a cutting pattern between the first and second active contacts;
wherein the first active contact comprises a first conductive pattern, where the first conductive pattern comprises:
a first body portion on the first source/drain pattern; and
a first via portion extended from the first body portion in a third direction;
wherein the second active contact comprises a second conductive pattern, where the second conductive pattern comprises:
a second body portion on the second source/drain pattern; and
a second via portion extended from the second body portion in the third direction;
wherein a top surface of the cutting pattern is farther from the substrate than a top surface of the first body portion and a top surface of the second body portion; and
the third direction is perpendicular to the top surface of the substrate.

11. The semiconductor device of claim 10, wherein:
each of the first and second conductive patterns has a first side surface and a second side surface, where the first and second side surfaces are respectively opposite to each other in the first direction;
each of the first and second active contacts comprises a barrier pattern on the first side surface of a corresponding one of the first and second conductive patterns; and
the cutting pattern is in contact with the second side surface of each of the first and second conductive patterns.

12. The semiconductor device of claim 10, wherein a width of the cutting pattern in the first direction ranges from 15 nm to 20 nm.

13. The semiconductor device of claim 10, further comprising:
a first interlayer insulating layer on the substrate and on the first and second source/drain patterns;
a second interlayer insulating layer on the first interlayer insulating layer;
wherein each of the first and second body portions penetrates the first and second interlayer insulating layers; and
wherein each of the first and second via portions extend to a region on the second interlayer insulating layer in the third direction.

14. The semiconductor device of claim 10, wherein:
the first body portion and the first via portion form a single object; and
the second body portion and the second via portion form a single object.

15. The semiconductor device of claim 10, further comprising a first metal layer on the first active contact, wherein the first metal layer comprises a metal line and the metal line is electrically connected to the first active contact through the first via portion.

16. The semiconductor device of claim 10, wherein the top surface of each of the first and second body portions is recessed toward the substrate.

17. The semiconductor device of claim 10, wherein a bottom surface of the cutting pattern closer to the substrate than a bottom surface of each of the first and second body portions.

18. The semiconductor device of claim 10, wherein a bottom surface of the cutting pattern is coplanar with or closer to the substrate than a bottom surface of the first body portion and a bottom surface of the second body portion.

19. A semiconductor device, comprising:
a substrate including a first active pattern and a second active pattern, where the first and second active patterns are spaced apart from each other in a first direction parallel to a top surface of the substrate;
a device isolation layer between the first and second active patterns;
a first source/drain pattern on the first active pattern;
a second source/drain pattern on the second active pattern;
a first interlayer insulating layer on the device isolation layer and on the first and second source/drain patterns;
a first active contact on the first source/drain pattern and penetrating a portion of the first interlayer insulating layer;
a second active contact on the second source/drain pattern and penetrating a portion of the first interlayer insulating layer;
a cutting pattern between the first and second active contacts,
wherein the first active contact comprises:
a first body portion on the first source/drain pattern; and
a first via portion extended from the first body portion in a third direction;
wherein the second active contact comprises:
a second body portion on the second source/drain pattern; and
a second via portion extended from the second body portion in the third direction; and
wherein a top surface of the cutting pattern is farther from the substrate than a top surface of each of the first and second body portions.

20. The semiconductor device of claim 19, wherein:
the first active contact comprises:
a first conductive pattern including the first body portion and the first via portion; and
a first barrier pattern between the first body portion of the first conductive pattern and the first interlayer insulating layer;
wherein the second active contact comprises:
a second conductive pattern including the second body portion and the second via portion; and
a second barrier pattern between the second body portion of the second conductive pattern and the first interlayer insulating layer; and
the cutting pattern is between the first and second conductive patterns and is in contact with the first and second conductive patterns.
